(19) United States
(12) Patent Application Publication
(10) Pub. No.: US 2025/0260606 A1
(43) Pub. Date: Aug. 14, 2025

(54) METHOD AND APPARATUS IN A WIRELESS COMMUNICATION SYSTEM

(71) Applicant: Samsung Electronics Co., Ltd., Suwon-si (KR)

(72) Inventors: Feifei SUN, Beijing (CN); Peng LIN, Beijing (CN); Di SU, Beijing (CN); Miao ZHOU, Beijing (CN)

(21) Appl. No.: 19/047,195

(22) Filed: Feb. 6, 2025

(30) Foreign Application Priority Data
Feb. 8, 2024 (CN) 202410178237.2
Apr. 3, 2024 (CN) 202410405018.3

(51) Int. Cl. H04L 27/04; H03M 5/12; H04L 25/49; H04W 68/10

(52) U.S. Cl. CPC H04L 27/04; H03M 5/12; H04L 25/4904; H04W 68/10

(57) ABSTRACT

The disclosure relates to a fifth generation (5G) or sixth generation (6G) communication system for supporting a higher data transmission rate. In accordance with another aspect of the disclosure, a user equipment (UE) in a wireless communication system is provided. The method includes receiving, by the UE, first information from a base station, performing, by the UE, digital baseband encoding of uplink information based on at least one of the first information or predefined digital baseband coding schemes, and transmitting, by the UE, the encoded uplink information.

### CROSS-REFERENCE TO RELATED APPLICATION(S)

This application is based on and claims priority under 35 U.S.C. § 119(a) of a Chinese patent application number 202410178237.2, filed on Feb. 8, 2024, in the Chinese Intellectual Property Office, and of a Chinese patent application number 202410405018.3, filed on Apr. 3, 2024, in the Chinese Intellectual Property Office, the disclosure of each of which is incorporated by reference herein in its entirety.

### BACKGROUND

### 1. Field

The disclosure relates to a technical field of wireless communication. More particularly, the disclosure relates to a base station and a user equipment in a wireless communication system and methods performed by the same.

### 2. Description of Related Art

Fifth generation (5G) mobile communication technologies define broad frequency bands such that high transmission rates and new services are possible, and can be implemented not only in “Sub 6 GHz” bands such as 3.5 GHz, but also in “Above 6 GHz” bands referred to as millimeter wave (mm Wave) including 28 GHz and 39 GHz. In addition, it has been considered to implement sixth generation (6G) mobile communication technologies (referred to as Beyond 5G systems) in terahertz (THz) bands (for example, 95 GHz to 3 THz bands) in order to accomplish transmission rates fifty times faster than 5G mobile communication technologies and ultra-low latencies one-tenth of 5G mobile communication technologies.

At the beginning of the development of 5G mobile communication technologies, in order to support services and to satisfy performance requirements in connection with enhanced Mobile BroadBand (eMBB), Ultra Reliable Low Latency Communications (URLLC), and massive Machine-Type Communications (mMTC), there has been ongoing standardization regarding beamforming and massive multi input multi output (MIMO) for mitigating radio-wave path loss and increasing radio-wave transmission distances in mmWave, supporting numerologies (for example, operating multiple subcarrier spacings) for efficiently utilizing mm Wave resources and dynamic operation of slot formats, initial access technologies for supporting multi-beam transmission and broadbands, definition and operation of BandWidth Part (BWP), new channel coding methods such as a Low Density Parity Check (LDPC) code for large amount of data transmission and a polar code for highly reliable transmission of control information, layer 2 (L2) pre-processing, and network slicing for providing a dedicated network specialized to a specific service.

Currently, there are ongoing discussions regarding improvement and performance enhancement of initial 5G mobile communication technologies in view of services to be supported by 5G mobile communication technologies, and there has been physical layer standardization regarding technologies such as Vehicle-to-everything (V2X) for aiding driving determination by autonomous vehicles based on information regarding positions and states of vehicles transmitted by the vehicles and for enhancing user convenience, New Radio Unlicensed (NR-U) aimed at system operations conforming to various regulation-related requirements in unlicensed bands, new radio (NR) user equipment (UE) Power Saving, Non-Terrestrial Network (NTN) which is UE-satellite direct communication for providing coverage in an area in which communication with terrestrial networks is unavailable, and positioning.

Moreover, there has been ongoing standardization in air interface architecture/protocol regarding technologies such as Industrial Internet of Things (IIoT) for supporting new services through interworking and convergence with other industries, Integrated Access and Backhaul (IAB) for providing a node for network service area expansion by supporting a wireless backhaul link and an access link in an integrated manner, mobility enhancement including conditional handover and Dual Active Protocol Stack (DAPS) handover, and two-step random access for simplifying random access procedures (2-step random access channel (RACH) for NR). There also has been ongoing standardization in system architecture/service regarding a 5G baseline architecture (for example, service based architecture or service based interface) for combining Network Functions Virtualization (NFV) and Software-Defined Networking (SDN) technologies, and Mobile Edge Computing (MEC) for receiving services based on UE positions.

As 5G mobile communication systems are commercialized, connected devices that have been exponentially increasing will be connected to communication networks, and it is accordingly expected that enhanced functions and performances of 5G mobile communication systems and integrated operations of connected devices will be necessary. To this end, new research is scheduled in connection with extended Reality (XR) for efficiently supporting Augmented Reality (AR), Virtual Reality (VR), Mixed Reality (MR) and the like, 5G performance improvement and complexity reduction by utilizing Artificial Intelligence (AI) and Machine Learning (ML), AI service support, metaverse service support, and drone communication.

Furthermore, such development of 5G mobile communication systems will serve as a basis for developing not only new waveforms for providing coverage in terahertz bands of 6G mobile communication technologies, multi-antenna transmission technologies such as Full Dimensional MIMO (FD-MIMO), array antennas and large-scale antennas, metamaterial-based lenses and antennas for improving coverage of terahertz band signals, high-dimensional space multiplexing technology using Orbital Angular Momentum (OAM), and Reconfigurable Intelligent Surface (RIS), but also full-duplex technology for increasing frequency efficiency of 6G mobile communication technologies and improving system networks, AI-based communication technology for implementing system optimization by utilizing satellites and Artificial Intelligence (AI) from the design stage and internalizing end-to-end AI support functions, and next-generation distributed computing technology for implementing services at levels of complexity exceeding the limit of UE operation capability by utilizing ultra-high-performance communication and computing resources.

The above information is presented as background information only to assist with an understanding of the disclosure. No determination has been made, and no assertion is made, as to whether any of the above might be applicable as prior art with regard to the disclosure.

### SUMMARY

In order to meet the increasing demand for wireless data communication services since the deployment of fourth generation (4G) communication systems, efforts have been made to develop improved 5G or pre-5G communication systems. Therefore, 5G or pre-5G communication systems are also called “Beyond 4G networks” or “PostLong Term Evolution (LTE) systems”.

In order to achieve a higher data rate, 5G communication systems are implemented in higher frequency (millimeter, mm Wave) bands, e.g., 60 GHz bands. In order to reduce propagation loss of radio waves and increase a transmission distance, technologies such as beamforming, massive multiple-input multiple-output (MIMO), full-dimensional MIMO (FD-MIMO), array antenna, analog beamforming and large-scale antenna are discussed in 5G communication systems.

In addition, in 5G communication systems, developments of system network improvement are underway based on advanced small cell, cloud radio access network (RAN), ultra-dense network, device-to-device (D2D) communication, wireless backhaul, mobile network, cooperative communication, coordinated multi-points (CoMP), reception-end interference cancellation, etc.

In 5G systems, hybrid frequency shift keying (FSK) and quadrature amplitude modulation (QAM) (FQAM) and sliding window superposition coding (SWSC) as advanced coding modulation (ACM), and filter bank multicarrier (FBMC), non-orthogonal multiple access (NOMA) and sparse code multiple access (SCMA) as advanced access technologies have been developed.

At present, in order to support passive/low-power-consumption tags to work better in the network, an enhanced transmission method is urgently needed.

Aspects of the disclosure are to address at least the above-mentioned problems and/or disadvantages and to provide at least the advantages described below. Accordingly, an aspect of the disclosure is to provide a base station and a user equipment in a wireless communication system and methods performed by the same.

Additional aspects will be set forth in part in the description which follows and, in part, will be apparent from the description, or may be learned by practice of the presented embodiments.

In accordance with an aspect of the disclosure, a method performed by a user equipment (UE) in a wireless communication system is provided. The method includes receiving, by the UE, first information from a base station, performing, by the UE, digital baseband encoding of uplink information based on at least one of the first information or predefined digital baseband coding schemes, and transmitting, by the UE, the encoded uplink information.

According to embodiments of the disclosure, the digital baseband coding includes converting a bit sequence of the uplink information into a digital baseband signal.

According to embodiments of the disclosure, the first information includes at least one of information about a digital baseband coding scheme, resource information, power control information, paging address message related to the UE, command message for the UE, data format, and purpose information.

According to embodiments of the disclosure, the information about a digital baseband coding scheme includes at least one of coding information and modulation information, wherein the coding information includes at least one of the following: coding scheme, subcarrier modulation information, chip information, chip length, subcarrier frequency.

According to embodiments of the disclosure, the performing digital baseband coding on uplink information based on the first information and/or predefined digital baseband coding schemes comprises at least one of the following performing digital baseband coding on the uplink information based on information about a digital baseband coding scheme included in the first information, performing digital baseband coding on the uplink information based on at least one of a capability of the UE, a strength of the received signal carrying the first information, and information of the content or purpose of the uplink information to be transmitted, performing digital baseband coding on the uplink information based on one of the predefined digital baseband coding schemes.

According to embodiments of the disclosure, the transmitting the encoded uplink information comprises at least one of transmitting the encoded uplink information on a received carrier, transmitting the encoded uplink information in a specific frequency domain, wherein the specific frequency domain is configured by the base station or predefined.

According to embodiments of the disclosure, the uplink information includes one or more of a preamble selected by the UE, identity information of the UE, user data of the UE, capability information of the UE, destination address information of the uplink information, status information of the UE, and information indicating the volume of the user data of the UE.

According to embodiments of the disclosure, the method further includes receiving a downlink signal, wherein the downlink signal carries information for confirming that the uplink information is successfully received, wherein the information for confirming that the uplink information is successfully received includes at least one of the following: identity information of the UE, a preamble in the uplink information, time domain and/or frequency domain resources used for transmitting the uplink information, and chip information used for transmitting the uplink information.

In accordance with another aspect of the disclosure, a method performed by a base station in a wireless communication system is provided. The method includes transmitting, by the base station, first information to a user equipment (UE), and receiving, by the base station, encoded uplink information, wherein the encoded uplink information is obtained by performing digital baseband coding on uplink information based on at least one of the first information or predefined digital baseband coding schemes.

According to embodiments of the disclosure, the digital baseband coding includes converting a bit sequence of the uplink information into a digital baseband signal.

According to embodiments of the disclosure, the first information includes at least one of information about a digital baseband coding scheme, resource information, power control information, paging address message related to the UE, command message for the UE, data format, and purpose information.

According to embodiments of the disclosure, the information about a digital baseband coding scheme includes at least one of coding information and modulation information, wherein the coding information includes at least one of the following: coding scheme, subcarrier modulation information, chip information, chip length, subcarrier frequency.

According to embodiments of the disclosure, the encoded uplink information includes at least one of uplink information after performing digital baseband coding on the uplink information based on information about a digital baseband coding scheme included in the first information, uplink information after performing digital baseband coding on the uplink information based on at least one of a capability of the UE, a strength of the received signal carrying the first information, and information of the content or purpose of the uplink information to be transmitted, uplink information after performing digital baseband coding on the uplink information based on one of the predefined digital baseband coding schemes.

According to embodiments of the disclosure, the receiving encoded uplink information includes at least one of receiving the encoded uplink information transmitted by the UE on a received carrier, receiving the encoded uplink information transmitted by the UE in a specific frequency domain, wherein the specific frequency domain is configured by the base station or predefined.

According to embodiments of the disclosure, the uplink information includes one or more of a preamble selected by the UE, identity information of the UE, user data of the UE, capability information of the UE, destination address information of the uplink information, status information of the UE, and information indicating the volume of the user data of the UE.

According to embodiments of the disclosure, the method further includes transmitting a downlink signal to the UE, wherein the downlink signal carries information for confirming that the uplink information is successfully received, wherein the information for confirming that the uplink information is successfully received includes at least one of the following: identity information of the UE, a preamble in the uplink information, time domain and/or frequency domain resources used for transmitting the uplink information, and chip information used for transmitting the uplink information.

In accordance with another aspect of the disclosure, a user equipment (UE) in a wireless communication system is provided. The UE includes a transceiver configured to receive and transmit a signal, memory storing one or more computer programs, and one or more processors communicatively coupled to the transceiver and the memory wherein one or more computer programs include computer-executable instructions that, when executed by the one or more processors individually or collectively, cause the UE to receive first information from a base station, performing digital baseband encoding of uplink information based on at least one of the first information or predefined digital baseband coding schemes, and transmit the encoded uplink information.

In accordance with another aspect of the disclosure, a base station in a wireless communication system is provided The base station includes a transceiver configured to transmit and receive signals, and a controller coupled to the transceiver and configured to perform a method performed by a base station in a wireless communication system according to embodiments of the disclosure.

In accordance with another aspect of the disclosure, one or more non-transitory computer-readable storage media storing one or more computer programs including computer-executable instructions that, when executed by one or more processors, of a user equipment (UE) individually or collectively, cause the UE to perform operations are provided. The operations include receiving, by the UE, first information from a base station, performing, by the UE, digital baseband encoding of uplink information based on at least one of the first information or predefined digital baseband coding schemes, and transmitting, by the UE, the encoded uplink information.

The uplink and/or downlink signal transmitting method for an Ambient Internet of Things (IoT) system provided by the disclosure can effectively support uplink and/or downlink communication of Ambient Internet of Things devices and improve communication efficiency.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION

The above and other aspects, features, and advantages of certain embodiments of the disclosure will be more apparent from the following description taken in conjunction with the accompanying drawings, in which:

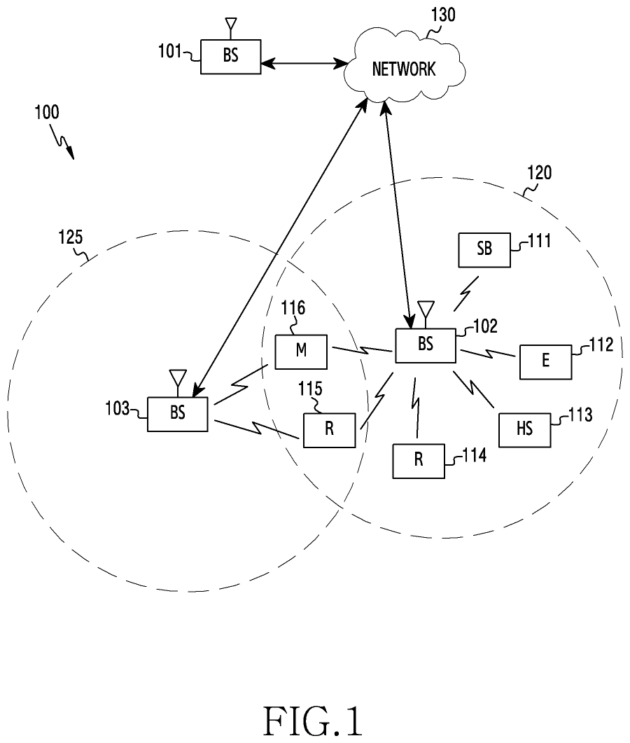

FIG. 1 illustrates an example wireless network 100 according to an embodiment of the disclosure;

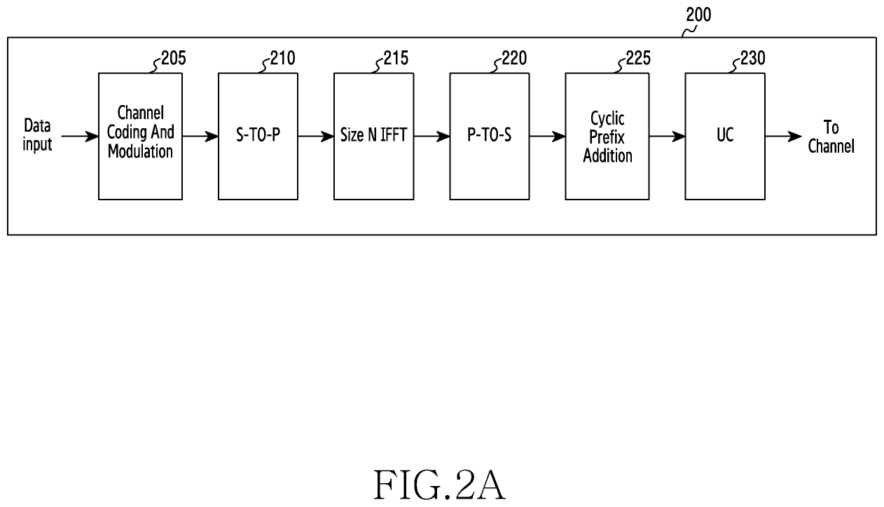

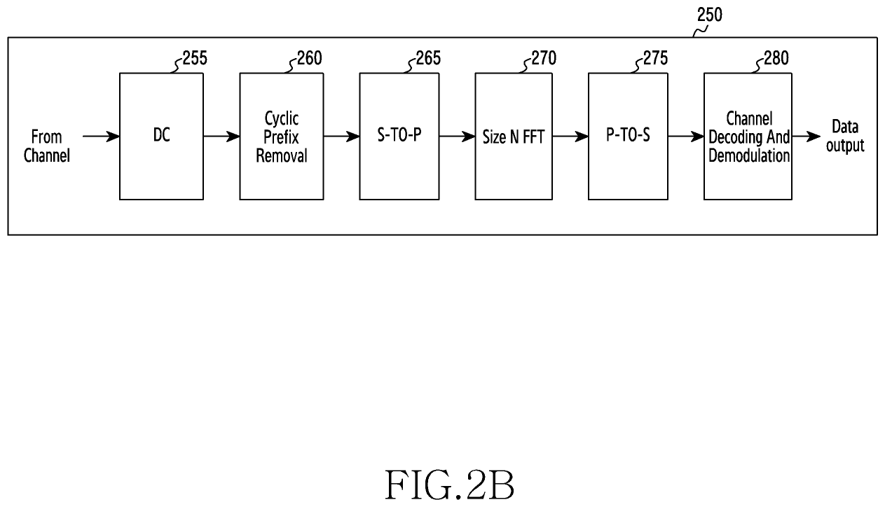

FIGS. 2A and 2B illustrate example wireless transmission and reception paths according to various embodiments of the disclosure;

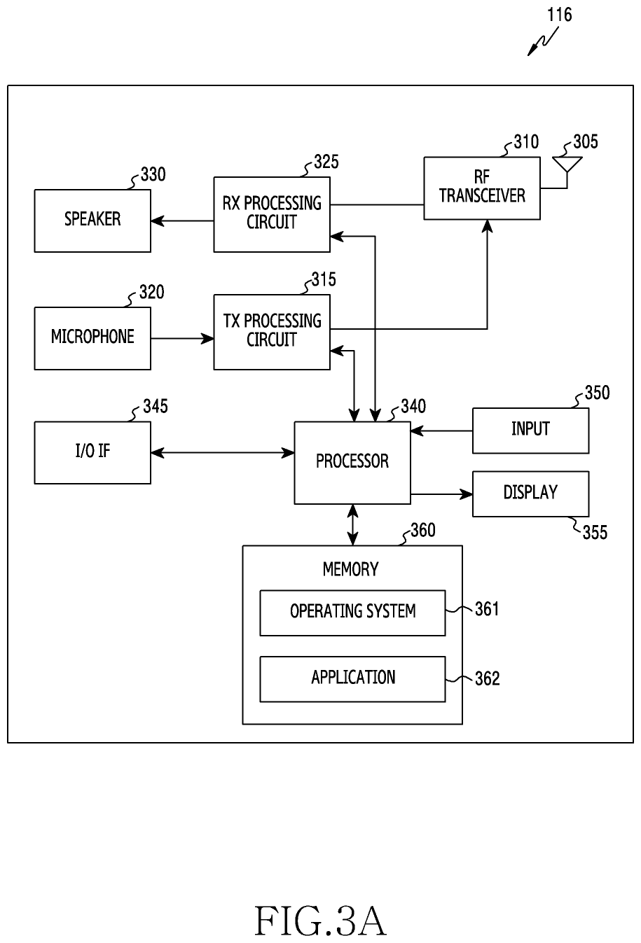

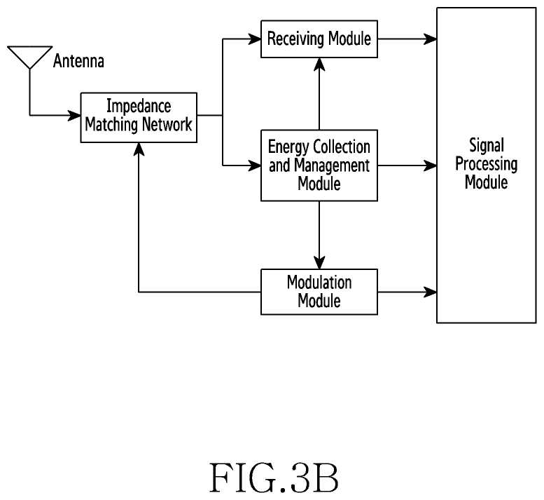

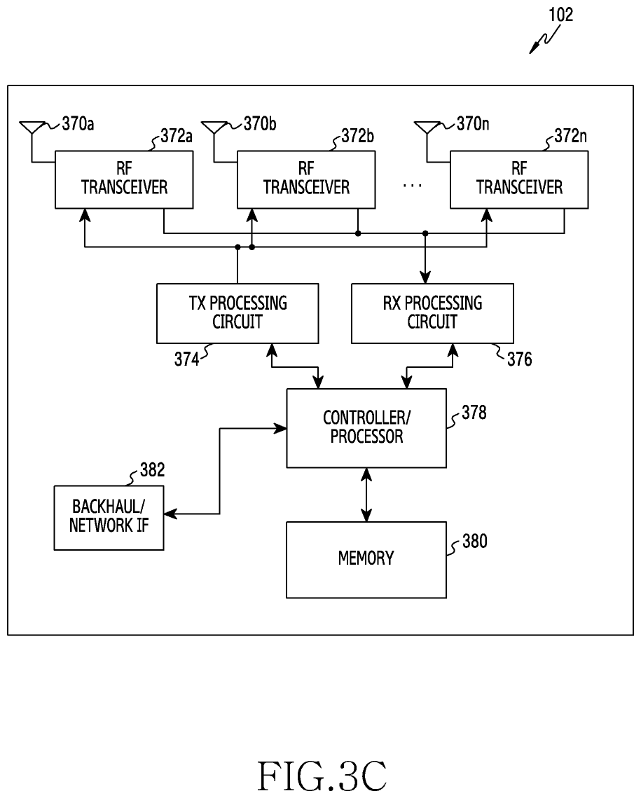

FIG. 3A illustrates an example UE according to an embodiment of the disclosure;

FIG. 3B illustrates a typical Ambient IoT (AIoT) device architecture according to an embodiment of the disclosure;

FIG. 3C illustrates an example gNodeB (gNB) according to an embodiment of the disclosure;

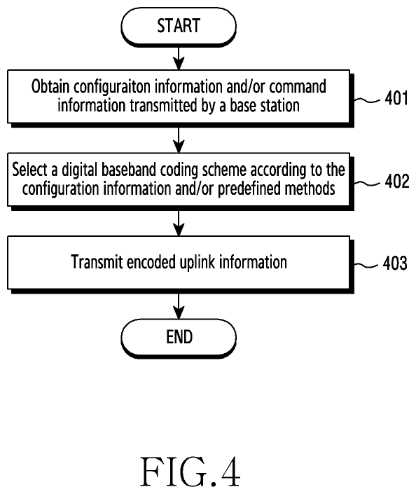

FIG. 4 illustrates a flowchart of a method performed by a UE (user equipment) in a wireless communication system according to an embodiment of the disclosure;

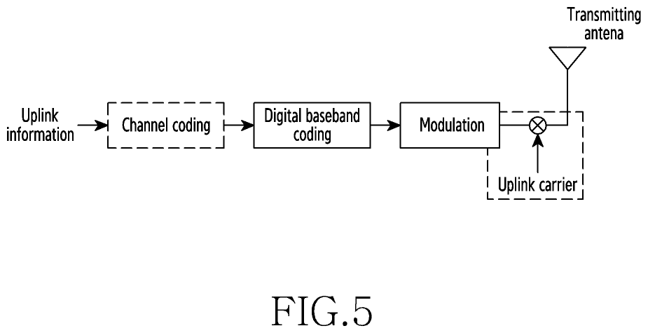

FIG. 5 illustrates a schematic diagram of a method performed by a UE (user equipment) in a wireless communication system according to an embodiment of the disclosure;

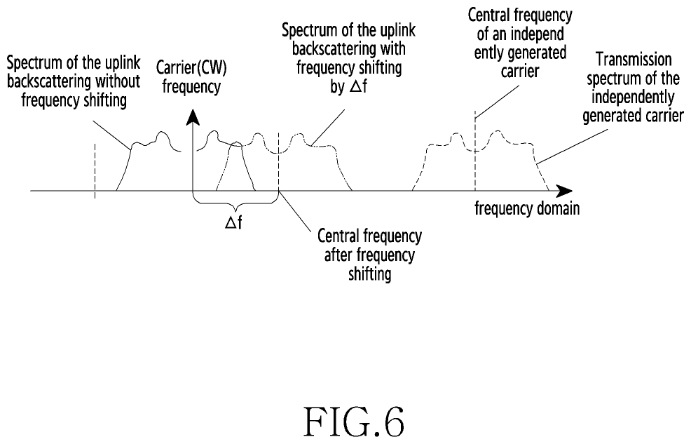

FIG. 6 illustrates a schematic diagram of backscattering uplink transmission and a frequency domain response of carrier wave (CW) according to an embodiment of the disclosure;

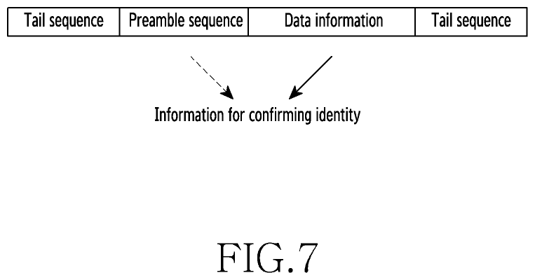

FIG. 7 illustrates a schematic diagram of a downlink signal format according to an embodiment of the disclosure;

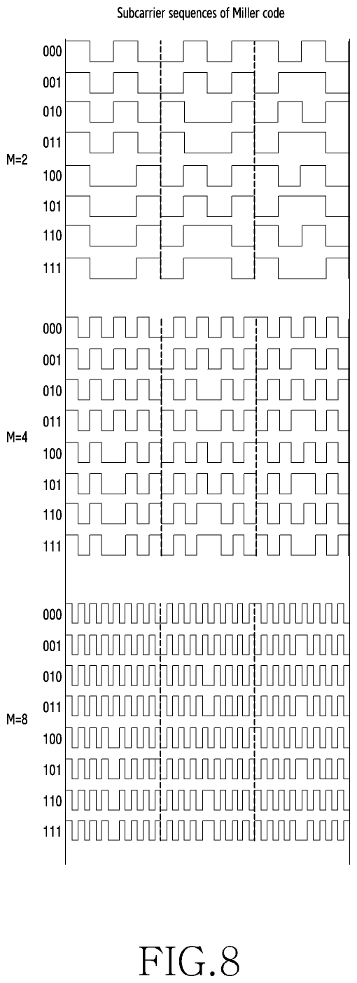

FIG. 8 illustrates a schematic diagram of chips of Miller code of different subcarrier sequences according to an embodiment of the disclosure;

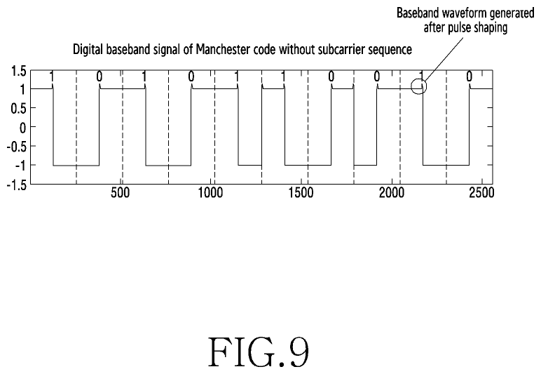

FIG. 9 illustrates digital baseband information of Manchester code without subcarrier sequence according to an embodiment of the disclosure;

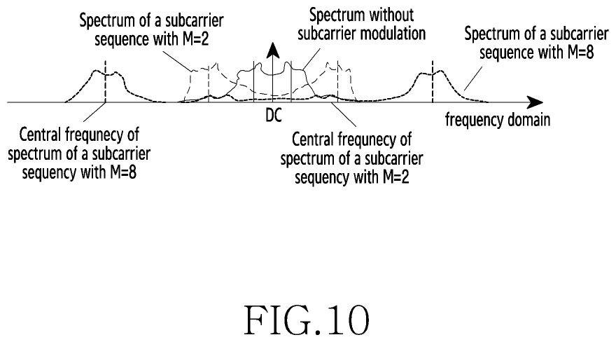

FIG. 10 illustrates a spectrum diagram of digital baseband coding schemes of different subcarrier sequences according to an embodiment of the disclosure;

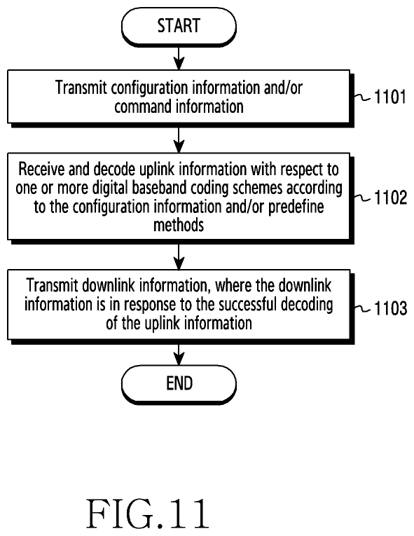

FIG. 11 illustrates a flowchart of a method performed by a base station side in a wireless communication system according to an embodiment of the disclosure;

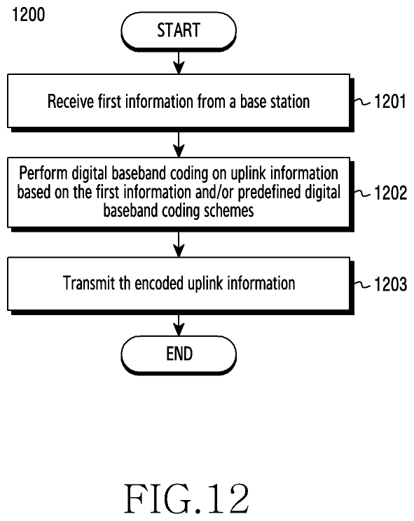

FIG. 12 illustrates a flowchart of a method performed by a user equipment (UE) in a wireless communication system according to an embodiment of the disclosure;

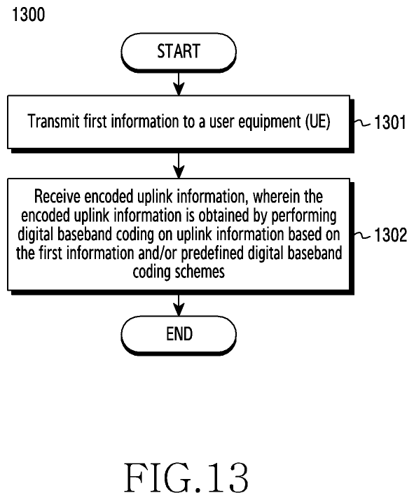

FIG. 13 illustrates a flowchart of a method performed by a base station in a wireless communication system according to an embodiment of the disclosure;

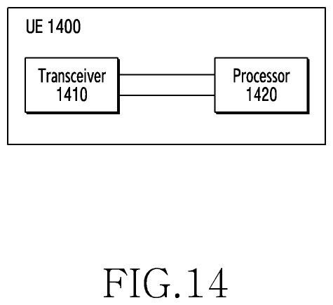

FIG. 14 illustrates a schematic diagram of a UE in a wireless communication system according to an embodiment of the disclosure;

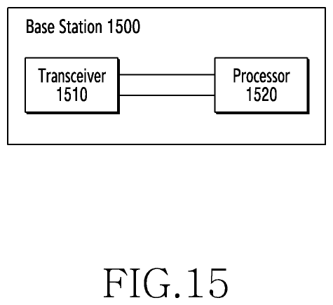

FIG. 15 illustrates a schematic diagram of a base station in a wireless communication system according to an embodiment of the disclosure.

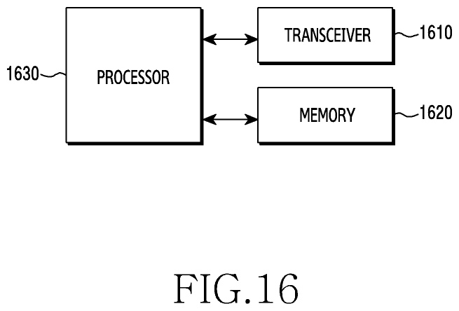

FIG. 16 illustrates a structure of a UE in a wireless communication system according to an embodiment of the disclosure; and

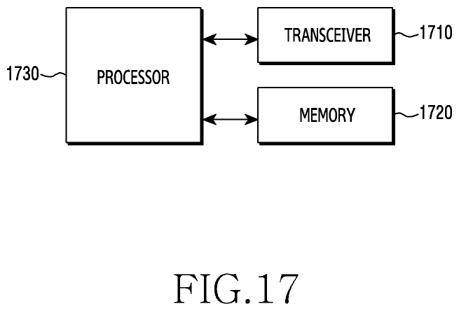

FIG. 17 illustrates a structure of a base station in a wireless communication system according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

The term “include” or “may include” refers to the existence of a corresponding disclosed function, operation or component which can be used in various embodiments of the disclosure and does not limit one or more additional functions, operations, or components. The terms such as “include” and/or “have” may be construed to denote a certain characteristic, number, step, operation, constituent element, component or a combination thereof, but may not be construed to exclude the existence of or a possibility of addition of one or more other characteristics, numbers, steps, operations, constituent elements, components or combinations thereof.

The term “or” used in various embodiments of the disclosure includes any or all of combinations of listed words. For example, the expression “A or B” includes A, may include B, or may include both A and B.

Unless defined differently, all terms used herein, which include technical terminologies or scientific terminologies, have the same meaning as that understood by a person skilled in the art to which the disclosure belongs. Such terms as those defined in a generally used dictionary are to be interpreted to have the meanings equal to the contextual meanings in the relevant field of art, and are not to be interpreted to have ideal or excessively formal meanings unless clearly defined in the disclosure.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

FIG. 1 illustrates an example wireless network 100 according to an embodiment of the disclosure. The embodiment of the wireless network 100 shown in FIG. 1 is for illustration only. Other embodiments of the wireless network 100 can be used without departing from the scope of the disclosure.

The wireless network 100 includes a gNodeB (gNB) 101, agNB 102, and a gNB 103. gNB 101 communicates with gNB 102 and gNB 103. gNB 101 also communicates with at least one Internet Protocol (IP) network 130, such as the Internet, a private IP network, or other data networks.

Depending on a type of the network, other well-known terms such as “base station” or “access point” can be used instead of “gNodeB” or “gNB”. For convenience, the terms “gNodeB” and “gNB” are used in this patent document to refer to network infrastructure components that provide wireless access for remote terminals. And, depending on the type of the network, other well-known terms such as “mobile station”, “user station”, “remote terminal”, “wireless terminal” or “user apparatus” can be used instead of “user equipment” or “UE”. For convenience, the terms “user equipment” and “UE” are used in this patent document to refer to remote wireless devices that wirelessly access the gNB, no matter whether the UE is a mobile device (such as a mobile phone or a smart phone) or a fixed device (such as a desktop computer or a vending machine).

gNB 102 provides wireless broadband access to the network 130 for a first plurality of User Equipments (UEs) within a coverage area 120 of gNB 102. The first plurality of UEs include a UE 111, which may be located in a Small Business (SB); a UE 112, which may be located in an enterprise (E); a UE 113, which may be located in a WiFi Hotspot (HS); a UE 114, which may be located in a first residence (R); a UE 115, which may be located in a second residence (R); a UE 116, which may be a mobile device (M), such as a cellular phone, a wireless laptop computer, a wireless PDA, etc. GNB 103 provides wireless broadband access to network 130 for a second plurality of UEs within a coverage area 125 of gNB 103. The second plurality of UEs include a UE 115 and a UE 116. In some embodiments, one or more of gNBs 101-103 can communicate with each other and with UEs 111-116 using 5G, Long Term Evolution (LTE), LTE-advanced (LTE-A), worldwide interoperability for microwave access (WiMAX) or other advanced wireless communication technologies.

The dashed lines show approximate ranges of the coverage areas 120 and 125, and the ranges are shown as approximate circles merely for illustration and explanation purposes. It should be clearly understood that the coverage areas associated with the gNBs, such as the coverage areas 120 and 125, may have other shapes, including irregular shapes, depending on configurations of the gNBs and changes in the radio environment associated with natural obstacles and man-made obstacles.

As will be described in more detail below, one or more of gNB 101, gNB 102, and gNB 103 include a two dimensional (2D) antenna array as described in embodiments of the disclosure. In some embodiments, one or more of gNB 101, gNB 102, and gNB 103 support codebook designs and structures for systems with 2D antenna arrays.

Although FIG. 1 illustrates an example of the wireless network 100, various changes can be made to FIG. 1. The wireless network 100 can include any number of gNBs and any number of UEs in any suitable arrangement, for example. Furthermore, gNB 101 can directly communicate with any number of UEs and provide wireless broadband access to the network 130 for those UEs. Similarly, each gNB 102- 103 can directly communicate with the network 130 and provide direct wireless broadband access to the network 130 for the UEs. In addition, gNB 101, 102 and/or 103 can provide access to other or additional external networks, such as external telephone networks or other types of data networks.

FIGS. 2A and 2B illustrate example wireless transmission and reception paths according to various embodiments of the disclosure. In the following description, the transmission path 200 can be described as being implemented in a gNB, such as gNB 102, and the reception path 250 can be described as being implemented in a UE, such as UE 116. However, it should be understood that the reception path 250 can be implemented in a gNB and the transmission path 200 can be implemented in a UE. In some embodiments, the reception path 250 is configured to support codebook designs and structures for systems with 2D antenna arrays as described in embodiments of the disclosure.

The transmission path 200 includes a channel coding and modulation block 205, a Serial-to-Parallel (S-to-P) block 210, a size N Inverse Fast Fourier Transform (IFFT) block 215, a Parallel-to-Serial (P-to-S) block 220, a cyclic prefix addition block 225, and an up-converter (UC) 230. The reception path 250 includes a down-converter (DC) 255, a cyclic prefix removal block 260, a Serial-to-Parallel (S-to-P) block 265, a size N Fast Fourier Transform (FFT) block 270, a Parallel-to-Serial (P-to-S) block 275, and a channel decoding and demodulation block 280.

In the transmission path 200, the channel coding and modulation block 205 receives a set of information bits, applies coding (such as Low Density Parity Check (LDPC) coding), and modulates the input bits (such as using Quadrature Phase Shift Keying (QPSK) or Quadrature Amplitude Modulation (QAM)) to generate a sequence of frequency-domain modulated symbols. The Serial-to-Parallel (S-to-P) block 210 converts (such as demultiplexes) serial modulated symbols into parallel data to generate N parallel symbol streams, where N is a size of the IFFT/FFT used in gNB 102 and UE 116. The size N IFFT block 215 performs IFFT operations on the N parallel symbol streams to generate a time-domain output signal. The Parallel-to-Serial block 220 converts (such as multiplexes) parallel time-domain output symbols from the Size N IFFT block 215 to generate a serial time-domain signal. The cyclic prefix addition block 225 inserts a cyclic prefix into the time-domain signal. The up-converter 230 modulates (such as up-converts) the output of the cyclic prefix addition block 225 to an RF frequency for transmission via a wireless channel. The signal can also be filtered at a baseband before switching to the RF frequency.

The RF signal transmitted from gNB 102 arrives at UE 116 after passing through the wireless channel, and operations in reverse to those at gNB 102 are performed at UE 116. The down-converter 255 down-converts the received signal to a baseband frequency, and the cyclic prefix removal block 260 removes the cyclic prefix to generate a serial time-domain baseband signal. The Serial-to-Parallel block 265 converts the time-domain baseband signal into a parallel time-domain signal. The Size N FFT block 270 performs an FFT algorithm to generate N parallel frequency-domain signals. The Parallel-to-Serial block 275 converts the parallel frequency-domain signal into a sequence of modulated data symbols. The channel decoding and demodulation block 280 demodulates and decodes the modulated symbols to recover the original input data stream.

Each of gNBs 101-103 may implement a transmission path 200 similar to that for transmitting to UEs 111-116 in the downlink, and may implement a reception path 250 similar to that for receiving from UEs 111-116 in the uplink. Similarly, each of UEs 111-116 may implement a transmission path 200 for transmitting to gNBs 101-103 in the uplink, and may implement a reception path 250 for receiving from gNBs 101-103 in the downlink.

Each of the components in FIGS. 2A and 2B can be implemented using only hardware, or using a combination of hardware and software/firmware. As a specific example, at least some of the components in FIGS. 2A and 2B may be implemented in software, while other components may be implemented in configurable hardware or a combination of software and configurable hardware. For example, the FFT block 270 and IFFT block 215 may be implemented as configurable software algorithms, in which the value of the size N may be modified according to the implementation.

Furthermore, although described as using FFT and IFFT, this is only illustrative and should not be interpreted as limiting the scope of the disclosure. Other types of transforms can be used, such as Discrete Fourier transform (DFT) and Inverse Discrete Fourier Transform (IDFT) functions. It should be understood that for DFT and IDFT functions, the value of variable N may be any integer (such as 1, 2, 3, 4, etc.), while for FFT and IFFT functions, the value of variable N may be any integer which is a power of 2 (such as 1, 2, 4, 8, 16, etc.).

Although FIGS. 2A and 2B illustrate examples of wireless transmission and reception paths, various changes may be made to FIGS. 2A and 2B. For example, various components in FIGS. 2A and 2B can be combined, further subdivided or omitted, and additional components can be added according to specific requirements. Furthermore, FIGS. 2A and 2B are intended to illustrate examples of types of transmission and reception paths that can be used in a wireless network. Any other suitable architecture can be used to support wireless communication in a wireless network.

FIG. 3A illustrates an example UE 116 according to an embodiment of the disclosure. The embodiment of UE 116 shown in FIG. 3A is for illustration only, and UEs 111-115 of FIG. 1 can have the same or similar configuration. However, a UE has various configurations, and FIG. 3A does not limit the scope of the disclosure to any specific implementation of the UE.

UE 116 includes an antenna 305, a radio frequency (RF) transceiver 310, a transmission (TX) processing circuit 315, a microphone 320, and a reception (RX) processing circuit 325. UE 116 also includes a speaker 330, a processor/controller 340, an input/output (I/O) interface 345, an input device(s) 350, a display 355, and memory 360. The memory 360 includes an operating system (OS) 361 and one or more applications 362.

The RF transceiver 310 receives an incoming RF signal transmitted by a gNB of the wireless network 100 from the antenna 305. The RF transceiver 310 down-converts the incoming RF signal to generate an intermediate frequency (IF) or baseband signal. The IF or baseband signal is transmitted to the RX processing circuit 325, where the RX processing circuit 325 generates a processed baseband signal by filtering, decoding and/or digitizing the baseband or IF signal. The RX processing circuit 325 transmits the processed baseband signal to speaker 330 (such as for voice data) or to processor/controller 340 for further processing (such as for web browsing data).

The TX processing circuit 315 receives analog or digital voice data from microphone 320 or other outgoing baseband data (such as network data, email or interactive video game data) from processor/controller 340. The TX processing circuit 315 encodes, multiplexes, and/or digitizes the outgoing baseband data to generate a processed baseband or IF signal. The RF transceiver 310 receives the outgoing processed baseband or IF signal from the TX processing circuit 315 and up-converts the baseband or IF signal into an RF signal transmitted via the antenna 305.

The processor/controller 340 can include one or more processors or other processing devices and execute an OS 361 stored in the memory 360 in order to control the overall operation of UE 116. For example, the processor/controller 340 can control the reception of forward channel signals and the transmission of backward channel signals through the RF transceiver 310, the RX processing circuit 325 and the TX processing circuit 315 according to well-known principles. In some embodiments, the processor/controller 340 includes at least one microprocessor or microcontroller.

The processor/controller 340 is also capable of executing other processes and programs residing in the memory 360, such as operations for channel quality measurement and reporting for systems with 2D antenna arrays as described in embodiments of the disclosure. The processor/controller 340 can move data into or out of the memory 360 as required by an execution process. In some embodiments, the processor/controller 340 is configured to execute the application 362 based on the OS 361 or in response to signals received from the gNB or the operator. The processor/controller 340 is also coupled to an I/O interface 345, where the I/O interface 345 provides UE 116 with the ability to connect to other devices such as laptop computers and handheld computers. I/O interface 345 is a communication path between these accessories and the processor/controller 340.

The processor/controller 340 is also coupled to the input device(s) 350 and the display 355. An operator of UE 116 can input data into UE 116 using the input device(s) 350. The display 355 may be a liquid crystal display or other display capable of presenting text and/or at least limited graphics (such as from a website). The memory 360 is coupled to the processor/controller 340. A part of the memory 360 can include random access memory (RAM), while another part of the memory 360 can include flash memory or other read-only memory (ROM).

Although FIG. 3A illustrates an example of UE 116, various changes can be made to FIG. 3A. For example, various components in FIG. 3A can be combined, further subdivided or omitted, and additional components can be added according to specific requirements. As a specific example, the processor/controller 340 can be divided into a plurality of processors, such as one or more central processing units (CPUs) and one or more graphics processing units (GPUs). Furthermore, although FIG. 3A illustrates that the UE 116 is configured as a mobile phone or a smart phone, UEs can be configured to operate as other types of mobile or fixed devices.

FIG. 3B illustrates a typical AIoT device architecture according to an embodiment of the disclosure.

A typical AIoT device architecture is shown in FIG. 3B, which includes an antenna, an impedance matching network, a receiving module, an energy collection and management module, a modulation module and a signal processing module. Herein, the impedance matching network may be implemented by a simple load circuit (such as series and parallel connection between resistors, capacitors and inductors), which can make the impedance Za of the antenna be conjugately matching with the impedance Zc of the load circuit, thus maximizing the energy transmitted by the antenna to the load circuit. The receiving module may be implemented by a low-power-consumption envelope detector and a signal comparator. Its input is the RF signal received by the antenna and its output is a digital baseband signal. The energy collection and management module may be constructed of a rectifier, a voltage limiting circuit and a voltage regulator circuit, which can convert RF signals into electric energy and provide a stable DC voltage for the load circuit. The modulation module (or backscattering modulation module) is constructed of a circuit with variable impedance. This module can make the input impedance of the whole load circuit mismatch with the antenna impedance by changing its circuit impedance, so as to increase the reflection coefficient of the AIoT device and make a part of the input RF signals reflected back. The change of the impedance may be controlled by the signal processing module. A common implementation is to change the impedance by switching switches. The signal processing module can demodulate and/or decode the digital baseband signal generated by the receiving module, and can control the modulation module for backscattering transmission.

FIG. 3C illustrates an example gNB 102 according to an embodiment of the disclosure. The embodiment of gNB 102 shown in FIG. 3C is for illustration only, and other gNBs of FIG. 1 can have the same or similar configuration. However, a gNB has various configurations, and FIG. 3C does not limit the scope of the disclosure to any specific implementation of a gNB. It should be noted that gNB 101 and gNB 103 can include the same or similar structures as gNB 102.

Referring to FIG. 3C, gNB 102 includes a plurality of antennas 370a-370n, a plurality of RF transceivers 372a-372n, a transmission (TX) processing circuit 374, and a reception (RX) processing circuit 376. In certain embodiments, one or more of the plurality of antennas 370a-370n include a 2D antenna array. gNB 102 also includes a controller/processor 378, memory 380, and a backhaul or network interface 382.

RF transceivers 372a-372n receive an incoming RF signal from antennas 370a-370n, such as a signal transmitted by UEs or other gNBs. RF transceivers 372a-372n down-convert the incoming RF signal to generate an IF or baseband signal. The IF or baseband signal is transmitted to the RX processing circuit 376, where the RX processing circuit 376 generates a processed baseband signal by filtering, decoding and/or digitizing the baseband or IF signal. RX processing circuit 376 transmits the processed baseband signal to controller/processor 378 for further processing.

The TX processing circuit 374 receives analog or digital data (such as voice data, network data, email or interactive video game data) from the controller/processor 378. TX processing circuit 374 encodes, multiplexes and/or digitizes outgoing baseband data to generate a processed baseband or IF signal. RF transceivers 372a-372n receive the outgoing processed baseband or IF signal from TX processing circuit 374 and up-convert the baseband or IF signal into an RF signal transmitted via antennas 370a-370n.

The controller/processor 378 can include one or more processors or other processing devices that control the overall operation of gNB 102. For example, the controller/processor 378 can control the reception of forward channel signals and the transmission of backward channel signals through the RF transceivers 372a-372n, the RX processing circuit 376 and the TX processing circuit 374 according to well-known principles. The controller/processor 378 can also support additional functions, such as higher-level wireless communication functions. For example, the controller/processor 378 can perform a Blind Interference Sensing (BIS) process such as that performed through a BIS algorithm, and decode a received signal from which an interference signal is subtracted. A controller/processor 378 may support any of a variety of other functions in gNB 102. In some embodiments, the controller/processor 378 includes at least one microprocessor or microcontroller.

The controller/processor 378 is also capable of executing programs and other processes residing in the memory 380, such as a basic OS. The controller/processor 378 can also support channel quality measurement and reporting for systems with 2D antenna arrays as described in embodiments of the disclosure. In some embodiments, the controller/processor 378 supports communication between entities such as web RTCs. The controller/processor 378 can move data into or out of the memory 380 as required by an execution process.

The controller/processor 378 is also coupled to the backhaul or network interface 382. The backhaul or network interface 382 allows gNB 102 to communicate with other devices or systems through a backhaul connection or through a network. The backhaul or network interface 382 can support communication over any suitable wired or wireless connection(s). For example, when gNB 102 is implemented as a part of a cellular communication system, such as a cellular communication system supporting 5G or new radio access technology or NR, LTE or LTE-A, the backhaul or network interface 382 can allow gNB 102 to communicate with other gNBs through wired or wireless backhaul connections. When gNB 102 is implemented as an access point, the backhaul or network interface 382 can allow gNB 102 to communicate with a larger network, such as the Internet, through a wired or wireless local area network or through a wired or wireless connection. The backhaul or network interface 382 includes any suitable structure that supports communication through a wired or wireless connection, such as an Ethernet or an RF transceiver.

The memory 380 is coupled to the controller/processor 378. A part of the memory 380 can include an RAM, while another part of the memory 380 can include a flash memory or other ROMs. In certain embodiments, a plurality of instructions, such as the BIS algorithm, are stored in the memory. The plurality of instructions are configured to cause the controller/processor 378 to execute the BIS process and decode the received signal after subtracting at least one interference signal determined by the BIS algorithm.

As will be described in more detail below, the transmission and reception paths of gNB 102 (implemented using RF transceivers 372a-372n, TX processing circuit 374 and/or RX processing circuit 376) support aggregated communication with frequency division duplex (FDD) cells and time division duplex (TDD) cells.

Although FIG. 3C illustrates an example of gNB 102, various changes may be made to FIG. 3C. For example, gNB 102 can include any number of each component shown in FIG. 3A. As a specific example, the access point can include many backhaul or network interfaces 382, and the controller/processor 378 can support routing functions to route data between different network addresses. As another specific example, although shown as including a single instance of the TX processing circuit 374 and a single instance of the RX processing circuit 376, gNB 102 can include multiple instances of each (such as one for each RF transceiver).

In order to make the purpose, technical schemes and advantages of the disclosure increasingly clear, the embodiments of the disclosure will be further described in detail with the drawings.

The text and drawings are provided as examples only to help readers understand the disclosure. They are not intended and should not be interpreted as limiting the scope of the disclosure in any way. Although certain embodiments and examples have been provided, based on the content disclosed herein, it is obvious to those skilled in the art that modifications to the illustrated embodiments and examples can be made without departing from the scope of the disclosure.

In the disclosure, user equipment (UE) can be used interchangeably with user, terminal, Tag, etc.

In the disclosure, information can also be used interchangeably with data.

In the Long Term Evolution (LTE) technology, a cellular Internet of Things technology includes Machine Type Communication (MTC) and Narrowband Internet of Things (NB-IoT). This kind of cellular Internet of Things communication technology has characteristics of low cost, low power consumption, high delay, wide coverage and massive accesses, etc., which may be used in Internet of Things scenarios such as smart cities, smart factories and remote meter reading, etc. In addition, Radio Frequency Identification (RFID), as a low-power-consumption or even passive communication mode of near-field communication, is also widely used in Internet of Things service.

For the near-field Internet of Things technology such as RFID, it has an access management mechanism of the cellular Internet of Things technology. However, due to the lack of a good control stage, communication between RFID Tags and Readers would collide, which affects the system capacity and results in a long access delay.

The existing cellular Internet of Things is connected and communicated with the network through a 2-step or 4-step random access procedure. Due to the complexity limitation of a Tag, it is not easy to directly apply the existing random access procedure for the cellular Internet of Things. In addition, in the RFID technology, Tag access is supported by an ALOHA or slotted ALOHA protocol. However, the access mode based on ALOHA or slotted ALOHA has a high collision probability and a long access time.

At present, in order to support passive/low-power-consumption tags to work better in the network, an enhanced transmission method is urgently needed.

The disclosure provides transmitting and receiving methods for an Internet of Things device with low cost and low power consumption.

For a low-complexity IoT device, methods for receiving downlink signals and transmitting uplink signals both are different from traditional wireless communication methods. The downlink reception is mainly performed based on envelope detection, and the uplink transmission may be performed based on backscattering, or by generating uplink signals independently. Herein, the “generating uplink signals independently” may be that the UE generates a carrier of a specific frequency independently and modulates uplink information on the carrier, or the UE directly generates modulated information and shifts the modulated information to a specific frequency. Herein, the backscattering technology means that a device performs modulation based on a carrier wave (CW) existing in the environment or transmitted by other nodes, modulates its information on the CW transmitted by other nodes, and backscatters the modulated CW, thus completing the transmission of uplink signals. The transmitting device that transmits signals based on backscattering may not generate carrier waves carrying information, thus eliminating the need for radio frequency circuits such as amplifiers and mixers of traditional communication devices, thus greatly reducing the cost of the devices and the demand for power supply or batteries. For the devices that can generate uplink carriers independently, although the power consumption will increase, the uplink transmission thereof is more flexible and collision and interference can be better avoided, etc. In the disclosure, because the transmission of such IoT devices mainly relies on ambient signals, such IoT devices are named as Ambient IoT (AIoT) devices (also referred to as Tags), the naming of which is mainly for the convenience of description and is not used to limit the scope of the devices.

In the AIoT system, transmission of signals/channels of data and services may be directly transmitted between a base station and an AIoT device (such as a tag); or it may be transmitted via an intermediate node. For example, the base station transmits information related to the AIoT device to the intermediate node, and the intermediate node transmits data to the AIoT device; and the AIoT device transmits data to the intermediate node, and the intermediate node then transmits the information related to the AIoT device to the base station.

In this specification, for the service of an AIoT device, a principle similar to the traditional cell communication is adopted, that is, the transmission transmitted by the base station or intermediate node to the AIoT device is called downlink transmission, and the transmission transmitted by the AIoT device to the base station or intermediate node is called uplink transmission. In addition, the transmission related to the AIoT device transmitted by the base station to the intermediate node may also be called downlink transmission, and the transmission related to the AIoT device transmitted by the intermediate node to the base station may also be called uplink transmission. Unless otherwise specified in this specification, the uplink/downlink transmission corresponds to a relationship between the transmitting and receiving nodes, and is not used to limit whether the transmission occurs on uplink or downlink resources. For example, the uplink transmission in the AIoT system may also be transmitted and received in a downlink frequency band in an FDD system, and the downlink transmission in the AIoT system may also be transmitted and received in an uplink slot in a TDD system.

The base station mentioned in this specification may also be replaced by other devices, such as a communication device which is an external attachment of a base station, a relay node, an IAB node, a repeater node, a sidelink node, a central unit of a base station, a distributed unit of a base station, a control plane part of a central unit of a base station, a user plane part of a central unit of a base station, etc. Any mechanism applicable to the base station in this specification can also be similarly used in the scenario where the base station is replaced by the other nodes, and the description thereof will not be repeated. Herein, the difference between a communication device which is an external attachment of a base station and a base station may include: the device can transmit DL signals/channels on an UL frequency band in an FDD system and on an UL time unit in a TDD system, including transmitting DL signals/channels corresponding to the communication between the base station and the UE and DL signals/channels corresponding to the communication between the base station and the AIoT device.

The UE mentioned in this specification includes a device node in the AIoT system, which may be a specific type of node or device, such as a device of a tag type. The UE may also be called user or user equipment. For simplicity, this specification is described by means of a UE.

The base station mentioned in this specification may be a specific type of node or device, such as a base station, a relay node, a reader and other devices. The base station may be deployed in the same location with communication nodes, or it may be an existing communication node which possesses a function of communicating with an AIoT device by upgrading. The node can be a relay node, an IAB node, a repeater node, a sidelink node, a user handheld device, and the like. For simplicity, this specification is described by means of a base station. In addition, in this specification, transmitting the downlink of the AIoT, receiving the uplink of the AIoT, and powering the AIoT device may be implemented through different nodes.

In the embodiments of the disclosure, unless otherwise specified, configuration information includes at least one of information configured by a base station, information indicated in a received signaling, information configured by a higher layer, and preconfigured information. Further, it may be a set of configuration information obtained by the above methods; or it may be multiple sets of configuration information obtained by the above methods, from which the UE or node can select a set of configuration information to use according to predefined conditions; or it may be a set of configuration information obtained by the above methods which contains a plurality of subsets, from which the UE or node can select a subset to use according to predefined conditions.

The disclosure provides an uplink and/or downlink transmission method for an AIoT system. The method can support simultaneous transmission of multiple users, thus improving communication efficiency. When the method is used for contention-based uplink transmission, the access collision probability and/or delay can be reduced. In the following, uplink transmission is described as an example.

FIG. 4 illustrates a flowchart of a method performed by a user equipment (UE) in a wireless communication system according to an embodiment of the disclosure.

Referring to FIG. 4, the method may include: Operation 401: obtain configuration information and/or command information transmitted by a base station.

Herein, the configuration information and/or command information includes at least one of the following: information related to digital baseband coding schemes, resource information for uplink transmission, power control information for uplink transmission, paging address message, command message, data format for uplink information transmission, purpose information for uplink transmission, etc. For convenience of description, configuration information and/or command information may also be referred to as first information herein.

Herein, the information related to digital baseband coding schemes may include modulation related information, baseband coding related information and the like. In addition, it may also include channel coding information, such as a coding rate of channel coding. Herein, the modulation related information includes modulation schemes, such as On-Off Keying (OOK) modulation, FSK modulation, Amplitude Shift Keying (ASK) modulation, QPSK modulation, QAM modulation, etc. The digital baseband coding related information includes at least one of the following: coding scheme, subcarrier modulation information, baseband waveform (chip) information, chip length and subcarrier frequency. The modulation related information and channel coding information may be jointly indicated, such as by indicating a row in a predefined modulation and coding scheme (MCS) table. This can reduce the bit overhead. Similarly, one or more of the modulation related information, baseband coding related information and channel coding information are configured to the UE by means of indicating one of predefined tables.

Herein, the coding scheme may be Line coding. In all these coding schemes, signal voltage is modified in a certain way to represent binary 0 and 1. For example, in a wired channel constructed of twisted pair or coaxial cable, transmission data is represented by electric pulse signals; and in a fiber channel, data values are represented by the changing of the intensity of optical pulses. In some examples, the coding scheme may also be a digital waveform representation of binary bits 0 and 1.

Coding scheme, subcarrier modulation information, baseband waveform (chip) information, chip length, subcarrier frequency and the like are information describing a conversion process of digital signal baseband coding in different aspects and degrees. For example, the waveform representing source bit 0 or source bit 1 is called a chip, and the process of mapping/converting a source bit sequence to a digital baseband signal is called code conversion or pattern coding or digital baseband coding. For another example, subcarrier modulation may also be called sub-carrier modulation, which is also a description of a waveform representing bits of 0 or 1. Subcarrier modulation is also a part of pattern coding.

The resource information for uplink transmission includes at least one of the following: time domain information (such as information indicating the location of time domain resources, such as time interval, index of slot, symbol or chip, etc.), and frequency domain information (such as carrier frequency, index of physical resource block (PRB), offset from a downlink signal, frequency domain offset from a received uplink carrier wave (CW), etc.).

Herein, the power control information for uplink transmission indicates power related information of uplink transmission to the UE. For example, the power control information for uplink transmission is a target reception power of the base station. The power control information for uplink transmission is only applicable to a type of UE that can generate uplink signals, and power control is not performed for UEs that rely on backscattering. Alternatively, the power control information for uplink transmission may be applied to all UE types. For another example, the power control information for uplink transmission is whether to perform uplink transmission amplification. Some types of UE (such as UE that relies on backscattering, or UE that generates uplink signals independently) can amplify the uplink signals and transmit them in order to enhance uplink coverage. Then, the power control information for uplink transmission may indicate whether the uplink signal needs to be amplified and then transmitted by 1 bit. In addition, 2 bits may be used to indicate more amplification levels. An indication of more than 1 bit is especially suitable for the type of UE that generates the uplink signal independently. In addition, the power control information for uplink transmission may also be a combination of the target reception power of the base station and information about whether to perform uplink transmission amplification, which is not limited herein.

Herein, the paging message includes identity information of one UE or multiple UEs (such as UE ID, UE group ID information, etc.). The command message includes instructions conveyed to the UE or information indicating a next state of the UE, such as instructions such as query, access, command, select, Random access, Kill, response, arbitration, ready, confirmation, open and security, etc.

Herein, the data format for uplink information transmission includes a data format that can be selected from the predefined data format for uplink information transmission, for example, a data format for random access, a data format for uplink information transmission, etc.

Herein, the purpose information for uplink transmission includes uplink information in response to instructions such as query, access, command, select, Random access, Kill, response, arbitration, ready, confirmation, open and security, etc. In addition, the purpose information for uplink transmission may also include at least one of the following: UE capability, data state information of the UE (such as the volume of the uplink data to be transmitted by the UE), and the current state of the UE (such as response, arbitration, ready, confirmation, open, security, etc.). Herein, the UE capability includes at least one of the following: whether an uplink carrier is required for backscattering uplink transmission; whether to support active uplink transmission; whether to support uplink signal amplification and transmission and/or a supported level and/or the supported number of levels of uplink signal amplification; whether to support amplification and reception of downlink signals and/or a supported level and/or the supported number of levels of downlink signal amplification; channel coding scheme and/or digital baseband coding scheme supported by the UE; modulation schemes supported by UE; whether the UE supports transmission frequency shifting based on backscattering uplink transmission and/or the levels of transmission frequency shifting based on backscattering uplink transmission supported by the UE, etc.

Operation 402: determine a digital baseband coding scheme according to the configuration information and/or predefined methods (or rules) and/or one or more predefined digital baseband coding schemes.

Operation 402 may include at least one of the following:
a digital baseband coding scheme included in or indicated by the configuration information is determined as the digital baseband coding scheme. For example, the configuration information may indicate one of one or more predefined digital baseband coding schemes. In addition, the configuration information may also include one or more digital baseband coding schemes. That is, in some implementations, the UE may perform digital baseband coding on the uplink information based on a digital baseband coding scheme included in or indicated by the configuration information or the first information.
one or more digital baseband coding schemes are predefined, and one of them is determined by the UE as the digital baseband coding scheme. In an example, a plurality of digital baseband coding schemes may be configured by a base station or may be predefined in the specification, and the UE selects one of the plurality of digital baseband coding schemes with a certain probability. In particular, one of a plurality of digital baseband coding schemes may be selected with an equal probability. Or the digital baseband coding scheme is selected according to a probability indicated in the configuration information. For example, a corresponding probability is configured for each of the plurality of digital baseband coding schemes. That is, in some implementations, the UE may perform digital baseband coding on the uplink information based on one of the predefined digital baseband coding schemes. For example, a digital baseband coding scheme may be predefined in the specification for digital baseband coding of the uplink information. Alternatively, a plurality of digital baseband coding schemes that can be used for uplink information may be predefined in the specification. The UE may determine one of them for digital baseband coding of uplink information according to predefined rules or according to the configuration or instructions of the base station.
a digital baseband coding scheme is determined according to the UE capability. For example, if the UE supports independent transmission of uplink signals, a digital baseband coding scheme A is selected, and if the UE supports backscattering uplink transmission, a digital baseband coding scheme B is selected. Further, if the UE supports the transmission frequency shifting of backscattering uplink transmission, a digital baseband coding scheme B1 is selected; and if the UE does not support the transmission frequency shifting of backscattering uplink transmission, a digital baseband coding scheme B0 is selected. The UE capability and digital baseband coding schemes may be defined in the specification in advance or configured by the base station. For another example, if the UE has a function of generating a carrier for uplink signal transmission, a digital baseband coding scheme C is selected; and if the UE does not have a function of generating a carrier for uplink signal transmission, a digital baseband coding scheme D is selected. In addition, the digital baseband coding scheme may be selected according to the downlink signal strength. For example, the base station may configure or the specification may predefine that, when the downlink signal strength is within an interval or above or below a threshold, a digital baseband coding scheme is selected. That is, a relationship between downlink signal strength and digital baseband coding schemes is configured by the base station or predefined.

Preferably, the UE selects a chip from a chip set, and performs digital baseband coding on the uplink information according to the chip. Digital baseband coding using different subcarriers or sub-carriers may be considered as different digital baseband coding schemes. For example, the transmission waveform of a modulating subcarrier for digital baseband coding may be a baseband waveform, or M times of a baseband waveform, which are considered as different digital baseband coding schemes. A waveform representing a source bit 0 or a source bit 1 is called a chip. Different modulating subcarriers may adopt different waveforms (also called different subcarrier sequences or different chips). The process from a source/information bit sequence to a digital baseband signal is called code conversion or pattern coding or digital baseband coding.

In addition, the UE may determine a digital baseband coding scheme according to the content or purpose of the uplink information to be transmitted. Or the UE may determine a digital baseband coding scheme according to a strength of the received signal carrying the configuration information. Specifically, the same or different digital baseband coding schemes may be configured or defined for different uplink information contents, different uplink information purposes, and different strength of the received signal carrying the configuration information. Then the UE may determine a corresponding digital baseband coding scheme according to the strength of the received signal carrying the configuration information, information of the content or purpose of the uplink information to be transmitted.

That is, in some implementations, the UE may perform digital baseband coding on the uplink information based on at least one of the UE capability, the strength of the received signal carrying the configuration information or first information, and the information of the content or purpose of the uplink information to be transmitted.

Operation 403: encode the uplink information according to the digital baseband coding scheme and transmit the same. Herein, operation 403 includes at least one of the following:
transmitting the encoded uplink information by backscattering on a received carrier; or, transmitting the encoded uplink information in a specific frequency domain location by an independently generated uplink signal. Herein the specific frequency domain is configured by the base station or specified in the specification in advance.

The uplink information includes one or more of the following: preamble, UE identity (ID) information, user data, UE capability information, address information, user status information, information indicating the volume of user data, etc.

The UE identity information may be a random number used to represent a UE ID, such as a random number RN16 with a length of 16 bits. The UE identity information may be user-specific ID information written in the register when accessing the network, or temporary ID information assigned by the base station for a UE, such as a Radio Network Temporary Identifier (RNTI).

The preamble may be used for uplink synchronization, channel estimation and other functions. The preamble may also be used to detect the uplink transmission of users, reduce collision between users, estimate the uplink Timing advance (TA), and indicate the identity of users, etc. For example, the UE may select a sequence from a sequence set for transmission. Herein, the sequence set is configured by a base station, for example, by the configuration information and/or command information. The sequence may include different subcarrier sequences and/or different bit sequences. Herein, different subcarrier sequences may enable the spectral energy to be concentrated in different locations, while different bit sequences may enable a receiver to detect different sequences by different peak locations when performing correlation detection (such as time domain correlation detection). Different subcarrier sequences and different bit sequences may be configured simultaneously, which further provides more orthogonality in frequency domain and code domain, thus supporting more users and/or reducing user collision probability. The UE may select a sequence from the sequence set with a certain probability (such as randomly) for transmission. Different users selecting different sequences can reduce the collision probability. For example, the frequency domain responses of different sequences are mainly concentrated in different frequency domain locations. Therefore, the base station/reader can filter and distinguish different frequency domain locations, and support uplink transmission of different UEs in a frequency division mode.

Herein, the UE capability may include at least one of the following: the UE can perform uplink transmission by means of backscattering, and the UE can independently generate uplink signals for transmission (also called that the UE can independently generate uplink carriers). Herein, UEs that can perform transmission by backscattering may be further divided into: UEs that have a capability of shifting and backscattering the frequency for uplink transmission in frequency domain, and UEs that do not have a capability of shifting and backscattering the frequency for uplink transmission in frequency domain. Further, the UE capability also includes a capability of shifting the frequency for uplink transmission by different extents in the frequency domain. For example, some UEs can perform shifting by several kHz to several tens of kHz, or some UEs can perform shifting by several MHz to several tens of MHZ, etc. The extent of frequency that can be shifted can be defined as different UE capabilities in the specification. For example, a frequency shifting capability 1 is that the frequency can be shifted by several kHz to several tens of kHz; and a frequency shifting capability 2 is that the frequency can be shifted by several MHz to several tens of MHz. In the actual specification, other thresholds can be used to define the frequency shifting (also called spectrum shifting) capability of the UE.

Herein, the address information includes a destination address of the uplink information transmission.

Herein, the user status information includes: response, arbitration, ready, confirmation, open, security and other statuses.

Herein, the information indicating the volume of user data can indicate the size (payload) of UE data by means of, for example, a buffer state report (BSR). In the communication system, a mapping relationship between indications and data sizes may be predefined. The UE selects an indication according to the current data in the buffer, where the indication is called BSR or Data volume (DV). The UE reports the current volume of data in the memory to the base station by reporting the BSR or DV, thus assisting the base station to allocate an uplink grant (UL grant) for uplink transmission to the UE. In an example, 1 bit is used to indicate whether the UE has data to be transmitted.

In addition, before or after operation 403, the UE may also select time domain and/or frequency domain resources for transmitting uplink information. The UE may perform channel coding on the uplink information. The UE may also determine whether to transmit the uplink information. UE may modulate the uplink information after channel coding and/or digital baseband coding. For example, the UE may generate uplink information to be transmitted after sequentially performing the following operations on source information: a) channel coding; b) adding cyclic redundancy check (CRC); c) digital baseband coding; d) modulation. Herein, a) and b) are optional. The UE selects time domain and/or frequency domain resources for transmitting the uplink information and transmits the coded and/or modulated uplink information.

In an example, channel coding and/or CRC addition would be performed for uplink, but would not be performed for downlink. This can reduce the implementation complexity of the terminal and reduce power consumption.

Herein, the UE may achieve the selection of time domain and/or frequency domain resources for transmitting the uplink information and the transmission of the coded and/or modulated uplink information by at least one of the following methods:
Method A: selecting a time domain and/or frequency domain resource from at least one set of time domain and/or frequency domain resources indicated in the configuration information and/or command information, and transmitting channel coded and/or digital baseband encoded uplink information on the selected time domain and/or frequency domain resource. This method enables dynamical indication of the location in time domain and/or frequency domain, which is more flexible.
Method B: coding the uplink information according to the digital baseband coding scheme, determining time domain and/or frequency domain resources for transmitting the uplink information, and transmitting the encoded uplink information on the time domain and/or frequency domain resources. Particularly, for a digital baseband coding scheme without subcarrier modulation, the transmission energy/spectrum thereof is concentrated near the carrier. For a digital baseband coding scheme with subcarrier modulation, the transmission energy/spectrum thereof is concentrated near the carrier plus an additional frequency offset. Therefore, after a digital baseband coding scheme is selected, the frequency domain resources for transmitting the uplink information are implicitly selected. The UE may determine frequency domain resources according to a subcarrier modulation waveform or a subcarrier frequency. The base station may configure a subcarrier frequency and subcarrier modulation information for the UE. In another example, the base station configures frequency domain resource information, and the base station may determine a digital baseband coding scheme according to the configured frequency domain resource information.

This method can save configuration overhead.

In addition, the UE may also determine whether to code and/or transmit the uplink information before coding and transmitting the uplink information according to the digital baseband coding scheme.

Herein, the determining whether to code and/or transmit the uplink information includes:

1) Whether to code and/or transmit the uplink information is determined with a certain probability.

For example, the UE generates a random number according to configuration of the base station (for example, between 0˜2^{Q}, where Q is configured by the base station). When the random number is a specific value (for example, when the random number is 0 or 2^{Q} or 2^{Q}-1 or any one or more specific values in the corresponding scope), the UE does not perform transmission, or when the random number is a specific value (for example, when the random number is 0 or 2^{Q} or 2^{Q}-1 or any one or more specific values in the corresponding scope), the UE performs transmission. This method can reduce the collision probability. In addition, for uplink information that are not transmitted yet, whether it can be transmitted may be determined with a higher (transmitting) probability (for example, a random number between 0˜2^{Q}-1 is generated) before uplink information can be transmitted the next time. Preferably, this method may be used to determine whether to perform transmission in the current time domain resources (such as slots). If the base station configures the UE with multiple time domain resources (such as slots) that can be used for uplink transmission, the Q value of each slot resource may be different. For example, the Q value of each time domain resource decreases in turn. For example, if the UE obtains n time domain resources for uplink information transmission, the Q value of the first time domain resource is q, the Q value of the second time domain resource is q−1, the Q value of the third time domain resource is q−2, and so on, and the Q value of the N-th time domain resource is q−(N-1). This can give the waiting UE more access opportunities. For example, since the first time domain resource may be different for different UEs, as for a certain time domain resource, the probabilities that each UE selects to perform transmission on the certain time domain resource may be different. For example, if, as for a resource M, UE1 may have waited for some time (for example, resource M is the third time resource for UE1) and UE2 has not waited (for example, resource M is the first time resource for UE2), then a random number generated with Q=q−2 is generated for UE1, and a random number generated with Q=q is generated for UE2. In this way, UE1 will have a greater probability to transmit uplink information on resource M. Similarly, different Q values may be configured for different frequency domain resources at the same time. The above-mentioned time resource can be replaced by frequency domain resource, code domain resource, spatial domain resource and so on, or it can be a resource defined by one or more dimensions (domains) of the time domain, frequency domain, spatial domain and code domain. This method can shorten the average waiting time of UE and make it fairer.

2) Whether to transmit uplink information is determined according to a downlink signal strength.

When the downlink signal strength is higher than a threshold, the uplink information is transmitted. This can improve the reliability of transmission. In this way, unnecessary interference caused by the UE with poor channel conditions to the UE with good channel conditions can be avoided, thereby improving the access success rate of the UE. In addition, different thresholds can be configured or predefined for UEs with different UE capabilities. This can make the success rate of uplink transmission of UEs with different capabilities close to each other.

In addition, if the UE determines not to perform transmission in the current slot, the UE may further determine time information related to back-off. The UE generates a random number according to configuration of the base station (for example, between 0˜2^{Q}, where Q is configured by the base station). When the random number is a specific value or within a specific interval, a back-off of several time units (e.g. slots, symbols, milliseconds, microseconds, etc.) may be performed. The mapping relationship between the random numbers and the back-off time may be configured by the base station or predefined in the specification. In addition, the UE may determine the time information related to the back-off according to the configuration of the base station. For example, the base station may indicate the back-off time of one or a group of UEs in the configuration or command information. In this way, the base station can control the waiting time of the UEs, which is more flexible.

In another example, the UE may first determine whether to perform transmission on a certain time domain resource. If the UE determines to perform transmission on a certain time domain resource (for example, slots within a period of time after a certain downlink signal), it encodes the uplink information and transmit it on the certain time domain resource. Herein, the certain time domain resource may be one or more of a certain session, a certain slot, and a period of time indicated or defined after a certain downlink channel or signal (such as downlink channel or signal indicating synchronization, downlink channel or signal indicating time resources, downlink channel or signal indicating downlink information, and downlink signal or channel defining or indicating a session), etc.

For example, the UE first determines a time domain resource for transmission according to the configuration of the base station. Specifically, the configuration information of the base station indicates a plurality of time domain resources. The UE determines one of the plurality of time domain resources for transmission according to predefined rules, for example, selecting one of the resources with equal probability. For another example, multiple time domain resources and multiple digital baseband coding schemes can be configured in the configuration information of the base station. The UE selects one combination of all or part (such as predefined or configured part) of the combinations of the multiple time domain resources and multiple digital baseband coding schemes with a certain probability (such as equal probability). Or, the UE selects a time domain resource from the multiple time domain resources with a certain probability A (such as equal probability or unequal probability), and then selects a digital baseband coding scheme from the multiple digital baseband coding schemes with a certain probability B (such as equal probability or unequal probability). Or, the UE selects a digital baseband coding scheme from the multiple digital baseband coding schemes with a certain probability B (such as equal probability or unequal probability), and then selects a time domain resource from the multiple time domain resources with a certain probability A (such as equal probability or unequal probability). Herein, the certain probability A and the certain probability B may be the same or different.

In addition, multiple sequences (e.g., multiple preamble sequences and/or multiple spreading sequences) may also be configured in the configuration information of the base station. The UE selects one sequence from the multiple sequences for uplink transmission with a certain probability (such as equal probability or unequal probability). For example, the UE selects one of the multiple preamble sequences as the preamble sequence for uplink transmission. And/or, the UE selects one of the multiple spreading sequences, performs spreading on the data for uplink transmission, and then transmits the same.

More resources can be provided for users, collisions can be reduced and access success rate can be improved by means of the implementations through time domain, code domain and frequency domain (different digital baseband coding schemes or different frequency domain resources (such as different uplink carriers (CWs))).

FIG. 5 illustrates a schematic diagram of a method performed by a UE (user equipment) in a wireless communication system according to an embodiment of the disclosure.

Referring to FIG. 5, uplink information is transmitted on an uplink carrier after channel coding, digital baseband coding and modulation. Herein, channel coding may be or include one of the channel coding of such as block code, convolutional code, Polar code, LDPC code and Turbo code, etc. The coding scheme may be predefined or configured by the base station. In addition, the base station may configure or adjust parameters such as a code rate. For an AIoT system, due to the limited capability of the UE, channel coding is unnecessary to be performed, or the code rate may be reduced by simple repetition. In addition, cyclic redundancy check (CRC) may be added after the channel coding. CRC may also be added after the digital baseband coding for the uplink information. Whether to add CRC after channel coding and/or digital baseband coding may be determined by the configuration of the base station or a predefined method. The uplink information is digitally baseband coded after channel coding, or the uplink information can be directly digitally baseband coded without channel coding. Channel coding can improve the transmission robustness. The method without channel coding can reduce the complexity and power consumption of UE.

After digital baseband coding, the signal may be modulated. For the UE in the AIoT system, due to the design goal of low complexity and low power consumption, the modulation schemes thereof may be one or more of the following: On-Off Keying (OOK) modulation, Frequency Shift Keying (FSK) modulation, Amplitude Shift Keying (ASK) modulation, Phase Shift Keying (PSK) modulation, Quadrature Amplitude Modulation (QAM) modulation, etc., or the differential modulation schemes corresponding to the above modulation schemes, such as DFSK and DPSK. The modulation schemes thereof are not limited to the above examples.

Further, as shown in FIG. 5, the UE transmits the modulated signal on an uplink carrier. There are two types of UE (which may also be regarded as a UE capability). One type is that the UE needs to perform uplink transmission by backscattering. In this way, the environment (such as a base station or other nodes that can provide energy) needs to transmit a CW for the UE, and the UE modulates uplink information on the CW for transmission by backscattering. Some of the UEs performing transmission by backscattering can shift the frequency of uplink transmission by a certain extent, such as shifting the frequency of the backscattered uplink signal to a frequency location with a difference of Af from the frequency where the CW is located. The Af may be defined in the specification or indicated/configured by the base station. Frequency shifting of the backscattered transmission would consume a certain amount of energy, so the energy consumption thereof is greater than that of backscattering without frequency shifting. For a UE that does not support the frequency shifting of the backscattered uplink signal, it can only perform transmission at or near the frequency of the CW. This is because frequency shifting may be implemented to some extent by changing the digital baseband subcarrier information.

FIG. 6 illustrates a schematic diagram of backscattering uplink transmission and a frequency domain response of carrier wave (CW) according to an embodiment of the disclosure.

Referring to FIG. 6, the frequency spectrum of the uplink backscattering without frequency shifting is concentrated around the carrier frequency, while the frequency spectrum after frequency shifting by Af has a certain distance from the carrier. The base station may filter out the frequency-shifted and non-frequency-shifted backscattered uplink signals by filtering and perform demodulation thereon respectively.

Another type is that the UE can independently generate uplink signals for transmission (also called that the UE can independently generate uplink carriers). In this way, the UE can generate an uplink carrier through an oscillator and/or other devices, modulate a modulated uplink signal on the uplink carrier for transmission. Herein, the frequency domain location of the uplink carrier may be configured by the base station or specified in the specification in advance, where an absolute frequency domain location of the uplink carrier may be indicated or defined, or an offset to the location of the carrier where the received downlink signal is located may be indicated or defined. Herein, the offset may be 0, which means that the frequency domain location of the uplink carrier is the same as the frequency domain location of the carrier where the downlink signal is received. As shown in FIG. 6, the UE that generates carriers independently may generate a spectrum that is further away from the backscattered uplink transmission. In this way, within a certain bandwidth, both backscattered uplink transmission and uplink transmission with independently generated carriers can be supported, and furthermore, both backscattered uplink transmission with frequency shifting, backscattered uplink transmission without frequency shifting, and uplink transmission with independently generated carriers can be supported, thus improving the transmission efficiency.

After transmitting the uplink information (such as after operation 403), the UE further receives the downlink signal, which carries information for confirming the successful reception of the uplink information. Herein, the expression “carry” may mean that the downlink signal directly includes information for confirming the successful reception of the uplink information, or it may mean that the downlink signal indicates the information for confirming the successful reception of the uplink information through any specific signal. Herein, the information for confirming the successful reception of the uplink information includes at least one of the following: UE identity information; a preamble sequence in the uplink information; time domain and/or frequency domain resources occupied for transmitting the uplink information, and baseband coding related information used for transmitting the uplink information.

FIG. 7 illustrates a schematic diagram of a downlink signal format according to an embodiment of the disclosure.

Herein, tail bits (for example, the tail sequence as shown in the figure) may be added before and/or after the preamble sequence and/or data information, to determine the starting and/or ending location of the channel. Usually the tail bits may be specific bits, such as all-zero bits. Alternatively, a special chip sequence (or waveform) may be designed for the tail bits, for example, a waveform that does not conform to a digital baseband coding scheme, such as a waveform having a longer high level or a longer low level compared with a basic chip. The preamble sequence may be a known sequence or a sequence selected from a set of known sequences. The UE can perform downlink timing by detecting the preamble sequence. The UE may select a sequence from a set of known sequences according to the resource (time domain and/or frequency domain resource) and/or digital baseband coding scheme selected for transmitting the uplink information. For example, a preamble sequence modulated and transmitted by the same subcarrier (also called sub-carrier) as that used for transmitting the uplink information is selected. For another example, resources that can be used to transmit uplink information correspond to a set of known sequences, and a sequence may be selected according to the resource used for transmitting the uplink information. The downlink signal format in FIG. 7 further includes data information. Herein, the data information may include related information of UE identity information, such as a UE ID, UE group ID information, a random number randomly selected by the UE, a temporary ID (such as an RNTI) assigned by the base station for the UE, etc. The UE may determine whether it is a downlink signal transmitted in response to the uplink signal (e.g., as ACK information for an uplink signal) by checking the UE identity information in the data information. In an example, the UE can confirm the identity according to the preamble sequence and the data in the data information jointly. For example, only when both the subcarrier information used by the preamble sequence and the UE identity information transmitted in the data information are correct, the downlink signal can be confirmed as a downlink signal transmitted in response to the uplink signal.

The downlink signal format may also be suitable for transmitting uplink information. For uplink information carrying a random access request message or uplink information in response to a specific instruction, a guard interval needs to be set at the end. The guard interval can be used to protect inter-symbol interference between different users. This interference may be caused by propagation delay due to different channel propagation distances.

The data information of the downlink signal may also carry instructions conveyed to the UE, such as information indicating a next state of the UE (such as instructions such as query, access, command, select, Random access, Kill, response, arbitration, ready, confirmation, open and security, etc.), or an instruction for the UE to perform back off, etc. When the UE receives a back-off instruction, or when the UE does not receive information for confirming the identity, or when information for confirming the identity received by the UE is incorrect, the UE may perform retransmission. For example, the UE may determine new time domain, frequency domain and code domain resources to retransmit the coded signal. For another example, the UE may re-determine a digital baseband coding scheme, and re-code the uplink information and then transmit the same. For another example, the UE may re-determine the uplink information (e.g., a random code such as RN16), re-code and transmit it on new resources (the same digital baseband coding scheme may be adopted or the digital baseband coding scheme may be re-determined). In particular, the UE may perform retransmission only when one of the preamble sequence or data information is correct and/or both of them are incorrect. The UE needs to repeat the methods in operation 402 and/or operation 403 to re-select a digital baseband coding scheme and/or re-select uplink transmission resources and perform retransmission after receiving a next downlink signal indicating uplink transmission. Alternatively, the UE can back off for a certain period of time and perform retransmission. The back-off time may be indicated in the downlink information or calculated by the UE according to a predefined rule. Alternatively, the UE may perform uplink transmission on the next resource that can be used for uplink transmission indicated in the configuration information in operation 401, or perform uplink transmission on an uplink transmission resource selected from a next group of resources that can be used for uplink transmission indicated in the configuration information in operation 401. Further, the UE may determine whether to perform uplink transmission on the next uplink resource or one resource of the next group of uplink resources with a certain probability. Herein, the certain probability may be obtained according to the configuration information and/or predefined rules.

In a digital communication system, a waveform representing a source bit 0 or source bit 1 is called a chip. The process from a source bit sequence to a digital baseband signal is called code conversion or pattern coding. A chip may be a rectangular wave or another waveform. For example, the rectangular wave would be distorted after passing through a low-pass filter before transmission.

FIG. 8 illustrates a schematic diagram of Miller code chips of different subcarrier sequences according to an embodiment of the disclosure. Miller code, also known as delay modulation code, is a deformed bi-phase code. Its coding rule is: for the original symbol “1”, the symbol is represented by “no jump at the beginning, but a jump at the center point”.

Referring to FIG. 8, a Miller code with M=2 is represented by “0110” or “1001”, and a Miller code with M=4 is represented by “01011010” or “10100101”. When the information code is of continuous “1”s, the subsequent “1”s should be interleaving coded. The original symbol “0” is coded as a bi-polar non-return-to-zero code. As shown in FIG. 8, a Miller code with M=2 is represented by “1010” or “0101”, and a Miller code with M=4 is represented by “10101010” or “01010101”, that is, “no jump at the center point”. When the information code is of continuous “0”s, the subsequent “0” should be interleaving coded. In FIG. 8, the baseband waveforms (symbols) or subcarrier sequence information of Miller codes with M=2, M=4 and M=8 are different. The special symbol for a tail sequence mentioned above may be one of the symbols different from that used in this coding scheme. For example, it may be a special symbol such as 0111 or 1000, etc. This special symbol may be predefined in the specification. Herein, 0 stands for a low level and 1 stands for a high level. In an OOK modulation, 0 may represent that there is no signal transmission and 1 may represent that there is signal transmission.

FIG. 9 illustrates digital baseband information of Manchester code without subcarrier sequence according to an embodiment of the disclosure. Manchester code, also known as split-phase code, synchronous code and phase code, is a coding scheme that uses level jump to represent 1 or 0. Its change rule is simple, that is, each chip is represented by two level signals with different phases, that is, a periodic square wave, but the phases of code 0 and code 1 are just the opposite.

Referring to FIG. 9, for the original chip “1”, the chip is represented by “10”, and for the original chip “0”, the chip is represented by “01”. The original data “1010110010” in FIG. 9 may be represented as “10 01 10 01 10 10 01 01 10 01”. A chip with M=4 may be further designed for the Manchester code. For example, for the original chip “1”, the chip is represented by “01011010”, and for the original chip “0”, the chip is represented by “10100101”. Similarly, for the chip with M=8, for the original chip “1”, the chip is represented by “0101010110101010”, and for the original chip “0”, the chip is represented by “1010101001010101”. For the chip with M=16, for the original chip “1”, the chip is represented by “01010101010101011010101010101010”, and for the original chip “0”, the chip is represented by “10101010101010100101010101010101”.

The information related to the digital baseband coding schemes mentioned in the disclosure includes chip related information and/or modulation information. The chip related information includes at least one of the following:

### Coding Scheme

Herein, the coding scheme may be Line coding. In all these coding schemes, signal voltage is modified in a certain way to represent binary 0 and 1. For example, in a wired channel constructed of twisted pair or coaxial cable, transmission data is represented by electric pulse signals; and in a fiber channel, data values are represented by the changing of the intensity of optical pulses. In some examples, the coding scheme may also be a digital waveform representation of binary bits 0 and 1.

Line coding can be divided into Uni-polar Encoding, Polar Encoding, Bipolar Encoding, Manchester Encoding, Differential Manchester Encoding and so on according to different voltage levels used. There are two types of the Uni-polar Encoding: uni-polar non-return-to-zero code (Unipolar NRZ) and uni-polar return-to-zero code (Unipolar RZ). There are two types of Polar Encoding: polar non-return-to-zero code (Polar NRZ) and polar return-to-zero code (Polar RZ). Herein, the polar non-return-to-zero code may further divided into the following two types: NRZL (NRZ-Level) and NRZI (NRZ-Invert). In addition, common Line Coding schemes further include: Miler coding, Bi-Phase Spacing coding (also called FM0 code), Pulse interval coding (PIE) code, etc. The Line Coding in the disclosure is not limited to the above coding schemes. In addition, the coding schemes in the disclosure further include other digital baseband coding schemes, such as block codes, convolutional codes and other forward error correction codes.

Sub-carrier modulation information, subcarrier modulation information, baseband waveform (chip) information or subcarrier sequence information.

The sub-carrier modulation information or subcarrier modulation information, baseband waveform (chip) information or subcarrier sequence information may be the “1010” or “0101” representing the bit “0” or the “0110” or “1001” representing the bit “1” in FIG. 8. The subcarrier modulation information or subcarrier sequence information may be indicated by the above-mentioned waveform/information bits, etc., or it may be expressed by an offset between the center frequency domain after subcarrier modulation and the uplink carrier frequency, or it may be expressed as a multiple of a chip clock without subcarrier modulation, for example, 2 times, 4 times or 8 times of the chip clock without subcarrier modulation. Alternatively, it may be expressed as a fraction of the pulse bandwidth of a chip without subcarrier modulation, for example, a fractional multiple of the pulse bandwidth of a chip without subcarrier modulation. For example, the subcarrier modulation information is ½, ¼ or ⅛ of the pulse bandwidth of a chip without subcarrier modulation.

### Chip Length

The chip length is a duration of a chip, such as 25 microseconds (us), etc. In order to better coexist with an NR system, the chip length of AIOT may be the length of one OFDM symbol. For example, for a subcarrier spacing of 15 KHz in an OFDM system, the length of an OFDM symbol is about 66.67 μs, and the length of an OFDM symbol corresponding to a subcarrier spacing of 30 kHz is about 33.33 μs. Alternatively, the symbol length of AIOT may be the length of an OFDM symbol plus a cycle prefix (CP). For example, after adding the normal CP length, the OFDM symbol length with a 15 kHz subcarrier spacing is about 71.35 μs, and the OFDM symbol length with a 15 kHz subcarrier spacing is about 35.68 μs. The cyclic prefixes of different OFDM symbols in NR and LTE systems are slightly different in order to adapt to the length of a slot (such as 1 millisecond (ms) or 0.5 ms). For example, the length of the first and seventh OFDM symbols in a slot are slightly longer than that of others. In this case, if the length of an OFDM symbol without CP is defined as one chip length, the CP can be added according to the principle of adding CP to OFDM symbols. If the OFDM symbol length including CP is defined as one chip length, the last waveform (0 or 1, low level or high level) or the first waveform (0 or 1, low level or high level) of the chip may be appropriately continued.

### Subcarrier Frequency

It may be the center frequency of a subcarrier frequency response, a signal bandwidth, a sideband signal bandwidth and half of a sideband signal bandwidth. It may be indicated by an explicit or implicit indication. For example, different subcarrier sequence information will have different center frequencies in the spectrum.

In the disclosure, sub-carrier modulation, subcarrier modulation information, baseband waveform (chip) information or subcarrier sequence information, and subcarrier frequency information can all represent a method of digital baseband modulation. Such as a subcarrier sequence in FIG. 8, it may correspond to a subcarrier sequence spectrum in FIG. 10. The central frequency of the spectrum of each subcarrier sequence, signal bandwidth, sideband signal bandwidth and half of the sideband signal bandwidth may be defined as a subcarrier frequency.

FIG. 10 illustrates a spectrum diagram of digital baseband coding schemes of different subcarrier sequences according to an embodiment of the disclosure.

Referring to FIG. 10, the center of the spectrum of subcarrier sequences with M=2 and M=8 deviates from the center frequency of the spectrum without subcarrier modulation, where the spectra with M=2 and M=8 are multiples of the symbol clock without subcarrier modulation. There are also some shifts in the spectra with M=2 and M=8. The base station can filter signals adopting digital baseband coding schemes with different subcarrier modulation, reserve the frequencies where the spectra thereof are concentrated and decode them respectively. Therefore, more users can be supported for uplink transmission at the same time. Different users randomly selecting different chips to perform accessing may further avoid collision and improve the access success rate. In addition, careful selection of a coding scheme can make the spectrum without carrier modulation deviate from DC, so that the base station can filter out the influence for CW, thus improving decoding accuracy.

The frequency domain responses of the digital baseband coding schemes described in the disclosure are mainly concentrated in different frequency domain locations. Therefore, the base station/reader can filter and distinguish different frequency domain locations, and realize uplink transmission in a frequency division mode for different users.

Determining a digital baseband coding scheme according to the configuration information and/or command information may specifically include at least one of the following:
Method 1: the digital baseband coding scheme indicated in the configuration information and/or command information is determined. For example, a Miller code is directly indicated in the configuration information, which may further indicate that the subcarrier modulation information is M=2. This method has low implementation complexity.
Method 2: one or more digital baseband coding schemes are pre-configured, and the UE determines one of them.

In an example, multiple digital baseband coding schemes may be configured by the base station or predefined in the specification, such as a Manchester code without subcarrier modulation, a Manchester code with M=2, a Manchester code with M=4, a Manchester code with M=8 and a Manchester code with M=16. The UE selects one of the above Manchester codes with different chips with a certain probability (for example, equal probability, or a probability with any other proportion defined or configured in advance). For example, UE1 selects a Manchester code with M=8, while UE2 may randomly select a Manchester code with M=2. In this case, UE1 and UE2 can transmit uplink information simultaneously, and the UEs can filter the frequency response locations corresponding to the Manchester code without subcarrier modulation, Manchester code with M=2, Manchester code with M=4, Manchester code with M=8 and Manchester code with M=16 respectively. The base station may detect that there is a UE performing transmission at the frequency domain location of the Manchester code with M=2 and another UE performing transmission at the frequency domain location of the Manchester code with M=16. If the channel conditions permit, the base station can successfully decode the information of UE1 and UE2 transmitted simultaneously.

Herein, the set of multiple digital baseband coding schemes configured by the base station or predefined in the specification may include chips with the same or different coding schemes, chips with the same or different sub-carrier modulation, and chips with the same or different baseband waveforms.
Method 3: a digital baseband coding scheme is determined according to UE capability. For example, if the UE supports transmitting uplink signals independently, a coding scheme without subcarrier modulation is selected. The frequency division of different users is realized by indicating carrier frequency locations different from that of the CW for UE. For another example, a UE that supports backscattering uplink transmission selects a coding scheme with subcarrier modulation. Further, if the UE supports the transmission frequency shifting of backscattering uplink transmission, a coding scheme without subcarrier modulation is selected; and if the UE does not support the transmission frequency shifting of backscattering uplink transmission, a coding scheme with subcarrier modulation is selected. The UE capability and digital baseband coding schemes can be defined in the specification in advance or configured by the base station. In an example, a digital baseband coding scheme, such as a coding scheme without subcarrier modulation (e.g., Manchester code or Miler code), is configured or predefined for a UE supporting independent transmission of uplink signals and/or a UE supporting transmission frequency shifting of backscattered uplink transmission. In addition, for the UE supporting independent transmission of uplink signals and/or the UE supporting transmission frequency shifting of backscattered uplink transmission, a central frequency for uplink transmission may be configured or predefined. For the UE that does not support the transmission frequency shifting of backscattering uplink transmission, a digital baseband coding scheme or a set of multiple digital baseband coding schemes (for example, a set including a Manchester code with M=2, a Manchester code with M=4, a Manchester code with M=8 and a Manchester code with M=16) are configured or predefined. For the UE that does not support the transmission frequency shifting of backscattering uplink transmission, one of the digital baseband coding schemes is selected in the set with a certain probability (equal probability or probability with any other proportion defined or configured in advance) for uplink transmission. For a UE with a specific capability, a digital baseband coding scheme is configured or predefined, while for a UE with another specific capability, a digital baseband coding scheme or a set including multiple digital baseband coding schemes is configured or predefined, and the UE with the another specific capability may select a digital baseband coding scheme from the set for uplink transmission.
Method 4: a digital baseband coding scheme is selected according to the content or purpose of the uplink information to be transmitted. Herein, different digital baseband coding schemes are used for uplink information in response to different commands and/or transmitting with different contents. For example, for uplink information transmission for random access and/or query, a digital baseband coding scheme for random access and/or query information transmission is selected. For example, for message in response to a paging message and/or a command, a digital baseband coding scheme for transmitting a message in response to a paging message and/or a command is selected. Specifically, for example, when transmitting uplink information for random access and/or query, a baseband waveform is selected from a plurality of baseband waveforms in a chip set with a certain probability for the transmission, for example, a baseband waveform is selected from Miler2, Miller4 and Miler8 for the transmission. For a message responding to a paging message and/or instruction, a digital baseband coding scheme indicated in the configuration information and/or command information (for example, Miler2 is indicated) is selected for transmission.

The above methods can be used in combination with each other. For example, some or a group of digital baseband coding schemes are determined according to one method, and then one of the digital baseband coding schemes is further determined according to another method. In addition, the above methods can be used in different cases according to the configuration or predefined rules.

In addition, the base station may configure at least one set of time domain and/or frequency domain resources for the UE. The UE may select one time domain and/or frequency domain resource from the at least one configured set of time domain and/or frequency domain resources for uplink transmission. Particularly, for contention-based uplink information transmission, such as the transmission of uplink information for random access or response to in response to a query signaling, etc. Using of multiple groups of time domain and/or frequency domain resources can reduce the collision probability. In particular, the base station may configure the at least one set of time domain and/or frequency domain resources in a downlink shared channel. Before the transmission of the uplink information, the base station may further transmit a command (such as a query command or a random access command) to one or more UEs to indicate one set of the at least one set of time domain and/or frequency domain resources, or one resource of the at least one set of time domain and/or frequency domain resources.

The UE receives configuration information and/or command information, which includes time domain information and/or frequency domain information. In an example, the time domain information is an offset, and its reference point can be a predefined or configured reference time (such as SFN=0) or the edge of a specific downlink channel or signal (such as the end location of the transmission of the configuration information).

The UE may perform retransmission or repetition of the transmitted uplink information according to the configuration or predefined rules. Specifically, the UE determines a new resource according to the instruction or configuration of the base station, and performs retransmission of the re-enencoded uplink information (the same digital baseband coding scheme may be adopted or the digital baseband coding scheme can be re-determined). In this way, the base station can combine the multiple received uplink signals (uplink signals or channels carrying the same uplink information), thus improving the decoding performance. In another example, the UE can acquire multiple resources (such as time domain resources) for retransmission, and use the same or different digital baseband coding schemes to perform encoding on the multiple resources for retransmission. The digital baseband coding scheme used each time may be determined according to predefined rules. For example, it may be predefined or specified that the same digital baseband coding scheme is used for each retransmission. For another example, the digital baseband coding scheme used for each retransmission is defined or configured in advance. For example, 4-Miler, 8-Miler, 4-Miler, 8-Miler, etc. may be used for retransmission in order. In this way, different UEs can be configured or defined with different orders for retransmission, which can well balance the decoding performance and power consumption of multiple users, thus reducing interference.

The method for determining the digital baseband coding scheme herein is suitable for contention-based uplink transmission and contention-free uplink transmission. For contention-free uplink transmission, the base station can still configure multiple digital baseband coding schemes, and the UE selects a digital baseband coding scheme for uplink transmission from them to encode the uplink transmission, which can reduce the uplink interference between different base stations (the interference is randomized) and improve the performance.

FIG. 11 illustrates a flowchart of a method performed by a base station side in a wireless communication system according to an embodiment of the disclosure.

Referring to FIG. 11, the method may include: Operation 1101: configuration information and/or command information is transmitted.

Herein, the configuration information and/or command information includes at least one of the following: information related to digital baseband coding schemes, resource information for uplink transmission, power control information for uplink transmission, paging address message, command message, data format for uplink information transmission, purpose information for uplink transmission, etc.

Operation 1102: uplink information is received and decoded with respect to one or more digital baseband coding schemes according to the configuration information and/or predefined methods (or rules).

The base station receives the uplink signal according to all digital baseband coding schemes that the UE may adopt. In addition, the base station can filter and decode the uplink signals transmitted in different frequency domain locations respectively. For example, one or more frequency domain locations corresponding to the subcarrier sequences after digital baseband coding are filtered, and the uplink information of the one or more subcarrier frequencies is decoded respectively.

Operation 1103: downlink information is transmitted, where the downlink information is in response to the successful decoding of the uplink information.

Herein, the downlink information includes UE identity information. The downlink information carries subcarrier sequence information including digital baseband codes. Herein, the subcarrier sequence information may be carried explicitly (indicated directly) or implicitly (time-frequency resources or codewords for receiving random access response are related to the subcarrier frequency).

In an example, the downlink information is transmitted in the format described in FIG. 7, which will not be repeated here.

It should be understood that, depending on the application scenarios, the various example aspects, methods, operations, processes, etc. described above in connection with the attached drawings can be combined and implemented in any way, including implementing in a different order from that shown in the drawings or deleting one or more operations, etc., and there is no limitation here.

Next, FIG. 12 illustrates a flowchart of a method 1200 performed by a user equipment (UE) in a wireless communication system according to an embodiment of the disclosure.

Referring to FIG. 12, a method 1200 performed by a UE in a wireless communication system according to embodiments of the disclosure may include: in operation 1201, receiving first information from a base station; in operation 1202, performing digital baseband coding on uplink information based on the first information and/or predefined digital baseband coding schemes; and in operation 1203, transmitting the encoded uplink information.

According to embodiments of the disclosure, the digital baseband coding includes converting a bit sequence of the uplink information into a digital baseband signal.

According to embodiments of the disclosure, the first information includes at least one of: information about a digital baseband coding scheme, resource information, power control information, paging address message related to the UE, command message for the UE, data format, and purpose information.

According to embodiments of the disclosure, the information about a digital baseband coding scheme includes at least one of coding information and modulation information, wherein the coding information includes at least one of the following: coding scheme, subcarrier modulation information, chip information, chip length, subcarrier frequency.

According to embodiments of the disclosure, the performing digital baseband coding on uplink information based on the first information and/or predefined digital baseband coding schemes comprises at least one of the following: performing digital baseband coding on the uplink information based on information about a digital baseband coding scheme included in the first information; performing digital baseband coding on the uplink information based on at least one of a capability of the UE, a strength of the received signal carrying the first information, and information of the content or purpose of the uplink information to be transmitted; performing digital baseband coding on the uplink information based on one of the predefined digital baseband coding schemes.

According to embodiments of the disclosure, the transmitting the encoded uplink information comprises at least one of: transmitting the encoded uplink information on a received carrier; transmitting the encoded uplink information in a specific frequency domain, wherein the specific frequency domain is configured by the base station or predefined.

According to embodiments of the disclosure, the uplink information includes one or more of: a preamble selected by the UE, identity information of the UE, user data of the UE, capability information of the UE, destination address information of the uplink information, status information of the UE, and information indicating the volume of the user data of the UE.

According to embodiments of the disclosure, the method further includes: receiving a downlink signal, wherein the downlink signal carries information for confirming that the uplink information is successfully received, wherein the information for confirming that the uplink information is successfully received includes at least one of the following: identity information of the UE, a preamble in the uplink information, time domain and/or frequency domain resources used for transmitting the uplink information, and chip information used for transmitting the uplink information.

FIG. 13 illustrates a flowchart of a method 1300 performed by a base station in a wireless communication system according to an embodiment of the disclosure.

Referring to FIG. 13, a method 1300 performed by a base station in a wireless communication system according to embodiments of the disclosure may include: in operation 1301, transmitting first information to a user equipment (UE); and in operation 1302, receiving encoded uplink information, wherein the encoded uplink information is obtained by performing digital baseband coding on uplink information based on the first information and/or predefined digital baseband coding schemes.

According to embodiments of the disclosure, the digital baseband coding includes converting a bit sequence of the uplink information into a digital baseband signal.

According to embodiments of the disclosure, the first information includes at least one of: information about a digital baseband coding scheme, resource information, power control information, paging address message related to the UE, command message for the UE, data format, and purpose information.

According to embodiments of the disclosure, the information about a digital baseband coding scheme includes at least one of coding information and modulation information, wherein the coding information includes at least one of the following: coding scheme, subcarrier modulation information, chip information, chip length, subcarrier frequency.

According to embodiments of the disclosure, the encoded uplink information includes at least one of: uplink information after performing digital baseband coding on the uplink information based on information about a digital baseband coding scheme included in the first information; uplink information after performing digital baseband coding on the uplink information based on at least one of a capability of the UE, a strength of the received signal carrying the first information, and information of the content or purpose of the uplink information to be transmitted; uplink information after performing digital baseband coding on the uplink information based on one of the predefined digital baseband coding schemes.

According to embodiments of the disclosure, the receiving encoded uplink information includes at least one of: receiving the encoded uplink information transmitted by the UE on a received carrier; receiving the encoded uplink information transmitted by the UE in a specific frequency domain, wherein the specific frequency domain is configured by the base station or predefined.

According to embodiments of the disclosure, the uplink information includes one or more of: a preamble selected by the UE, identity information of the UE, user data of the UE, capability information of the UE, destination address information of the uplink information, status information of the UE, and information indicating the volume of the user data of the UE.

According to embodiments of the disclosure, the method further includes: transmitting a downlink signal to the UE, wherein the downlink signal carries information for confirming that the uplink information is successfully received, wherein the information for confirming that the uplink information is successfully received includes at least one of the following: identity information of the UE, a preamble in the uplink information, time domain and/or frequency domain resources used for transmitting the uplink information, and chip information used for transmitting the uplink information.

It should be understood that methods 1200 and 1300 and any other methods according to embodiments of the disclosure may also include one or more of the methods or operations described above in connection with any examples or drawings, which are not repeated here.

Next, FIG. 14 illustrates a schematic diagram of a UE 1400 in a wireless communication system according to an embodiment of the disclosure.

Referring to FIG. 14, a UE 1400 according to embodiments of the disclosure (which may be, for example, an Ambient Internet of Things device or a Tag device as described above) may include a transceiver 1410 and a processor 1420. The transceiver 1410 may be configured to transmit and receive signals. The processor 1420 may be coupled to the transceiver 1410 and may be configured to (e.g., control the transceiver 1410 to) perform any method performed by a UE in a wireless communication system according to embodiments of the disclosure. Herein, a processor may also be called a controller.

FIG. 15 illustrates a schematic diagram of a base station 1500 in a wireless communication system according to an embodiment of the disclosure.

Referring to FIG. 15, a base station 1500 according to embodiments of the disclosure may include a transceiver 1510 and a processor 1520. The transceiver 1510 may be configured to transmit and receive signals. The processor 1520 may be coupled to the transceiver 1510 and may be configured to (e.g., control the transceiver 1510 to) perform any method performed by a UE in a wireless communication system according to embodiments of the disclosure. Herein, a processor may also be called a controller. Herein, a base station may also be called a node or a node device.

FIG. 16 illustrates a structure of a UE in a wireless communication system according to an embodiment of the disclosure.

Referring to FIG. 16, the UE according to an embodiment may include a transceiver 1610, memory 1620, and a processor 1630. The transceiver 1610, the memory 1620, and the processor 1630 of the UE may operate according to a communication method of the UE described above. However, the components of the UE are not limited thereto. For example, the UE may include more or fewer components than those described above. In addition, the processor 1630, the transceiver 1610, and the memory 1620 may be implemented as a single chip. Also, the processor 1630 may include at least one processor. Furthermore, the UE of FIG. 16 corresponds to the UE of the disclosure.

The transceiver 1610 collectively refers to a UE receiver and a UE transmitter, and may transmit/receive a signal to/from a base station or a network entity. The signal transmitted or received to or from the base station or a network entity may include control information and data. The transceiver 1610 may include a RF transmitter for up-converting and amplifying a frequency of a transmitted signal, and a RF receiver for amplifying low-noise and down-converting a frequency of a received signal. However, this is only an example of the transceiver 1610 and components of the transceiver 1610 are not limited to the RF transmitter and the RF receiver.

Also, the transceiver 1610 may receive and output, to the processor 1630, a signal through a wireless channel, and transmit a signal output from the processor 1630 through the wireless channel.

The memory 1620 may store a program and data required for operations of the UE. Also, the memory 1620 may store control information or data included in a signal obtained by the UE. The memory 1620 may be a storage medium, such as read-only memory (ROM), random access memory (RAM), a hard disk, compact disc read only memory (CD-ROM), and a digital versatile disc (DVD), or a combination of storage media.

The processor 1630 may control a series of processes such that the UE operates as described above. For example, the transceiver 1610 may receive a data signal including a control signal transmitted by the base station or the network entity, and the processor 1630 may determine a result of receiving the control signal and the data signal transmitted by the base station or the network entity.

FIG. 17 illustrates a structure of a base station in a wireless communication system according to an embodiment of the disclosure.

Referring to FIG. 17, the base station according to an embodiment may include a transceiver 1710, memory 1720, and a processor 1730. The transceiver 1710, the memory 1720, and the processor 1730 of the base station may operate according to a communication method of the base station described above. However, the components of the base station are not limited thereto. For example, the base station may include more or fewer components than those described above. In addition, the processor 1730, the transceiver 1710, and the memory 1720 may be implemented as a single chip. Also, the processor 1730 may include at least one processor. Furthermore, the base station of FIG. 17 corresponds to the base station of the disclosure.

The transceiver 1710 collectively refers to a base station receiver and a base station transmitter, and may transmit/receive a signal to/from a terminal (UE) or a network entity. The signal transmitted or received to or from the terminal or a network entity may include control information and data. The transceiver 1710 may include a RF transmitter for up-converting and amplifying a frequency of a transmitted signal, and a RF receiver for amplifying low-noise and down-converting a frequency of a received signal. However, this is only an example of the transceiver 1710 and components of the transceiver 1710 are not limited to the RF transmitter and the RF receiver.

Also, the transceiver 1710 may receive and output, to the processor 1730, a signal through a wireless channel, and transmit a signal output from the processor 1730 through the wireless channel.

The memory 1720 may store a program and data required for operations of the base station. Also, the memory 1720 may store control information or data included in a signal obtained by the base station. The memory 1720 may be a storage medium, such as read-only memory (ROM), random access memory (RAM), a hard disk, a CD-ROM, and a DVD, or a combination of storage media.

The processor 1730 may control a series of processes such that the base station operates as described above. For example, the transceiver 1710 may receive a data signal including a control signal transmitted by the terminal, and the processor 1730 may determine a result of receiving the control signal and the data signal transmitted by the terminal.

Those skilled in the art will understand that the illustrative embodiments described above are described herein and are not intended to be limiting. It should be understood that any two or more of the embodiments disclosed herein can be combined in any combination. In addition, other embodiments may be utilized and other changes may be made without departing from the spirit and scope of the subject matter presented herein. It will be readily understood that aspects of the disclosure, as generally described herein and shown in the drawings, can be arranged, substituted, combined, separated, and designed in various different configurations, all of which are contemplated herein.

Those skilled in the art will appreciate that the various illustrative logical blocks, modules, circuits, and operations described in the disclosure may be implemented as hardware, software, or a combination of both. In order to clearly illustrate this interchangeability between hardware and software, various illustrative components, blocks, modules, circuits, and operations are generally described in the form of their function sets. Whether such a function set is implemented as hardware or software depends on the specific application and the design constraints imposed on the overall system. Skilled people may implement the described functional set in different ways for each specific application, but such design decisions should not be interpreted as causing a departure from the scope of the disclosure.

The illustrative logical blocks, modules, and circuits described in the disclosure may be implemented in a general-purpose processor, a Digital Signal Processor (DSP), an Application Specific Integrated Circuit (ASIC), a Field Programmable Gate Array (FPGA) or other programmable logic devices, discrete gates or transistor logics, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors cooperating with a DSP core, or any other such configuration.

The operations of a method or algorithm described in the disclosure may be embodied directly in hardware, in a software module executed by a processor, or in a combination of the both. Software modules may reside in RAM memory, flash memory, ROM memory, EPROM memory, EEPROM memory, register, hard disk, removable disk, or any other form of storage media known in the art. A storage medium is coupled to a processor to enable the processor to read and write information from/to the storage medium. In the alternative, the storage medium may be integrated into the processor. The processor and storage medium may reside in an ASIC. The ASIC may reside in the user terminal. In the alternative, the processor and the storage medium may reside as separate components in the user terminal.

In one or more designs, the described functions may be implemented in hardware, software, firmware, or any combination thereof. If implemented in software, each function can be stored on or transmitted by a computer-readable medium as one or more instructions or codes. Computer-readable media include both computer storage media and communication media, and the latter includes any media that facilitates the transfer of computer programs from one place to another. The storage medium can be any available medium that can be accessed by a general-purpose or special-purpose computer.

What has been described above is only an embodiment of the disclosure, and is not used to limit the protection scope of the disclosure, which is determined by the appended claims.

Various embodiments of the disclosure may be implemented as computer-readable codes embodied on a computer-readable recording medium from a specific perspective. A computer-readable recording medium is any data storage device that can store data readable by a computer system. Examples of computer-readable recording media may include read-only memory (ROM), random access memory (RAM), compact disk read-only memory (CD-ROM), magnetic tape, floppy disk, optical data storage device, carrier (e.g., data transmission via the Internet), etc. Computer-readable recording media can be distributed by computer systems connected via a network, and thus computer-readable codes can be stored and executed in a distributed manner. Furthermore, functional programs, codes and code segments for implementing various embodiments of the disclosure can be easily explained by those skilled in the art to which embodiments of the disclosure are applied.

It will be understood that embodiments of the disclosure may be implemented in the form of hardware, software, or a combination of hardware and software. The software may be stored as program indications or computer-readable codes executable on a processor on a non-transitory computer-readable medium. Examples of non-transitory computer-readable recording media include magnetic storage media (such as ROM, floppy disk, hard disk, etc.) and optical recording media (such as CD-ROM, digital video disk (DVD), etc.). Non-transitory computer-readable recording media may also be distributed on computer systems coupled to a network, so that computer-readable codes are stored and executed in a distributed manner. The medium can be read by a computer, stored in memory, and executed by a processor. Various embodiments may be implemented by a computer or a portable terminal including a controller and memory, and the memory may be an example of a non-transitory computer-readable recording medium suitable for storing program(s) with indications for implementing embodiments of the disclosure. The disclosure may be realized by a program with code for concretely implementing the apparatus and method described in the claims, which is stored in a machine (or computer)-readable storage medium. The program may be electronically carried on any medium, such as a communication signal transmitted via a wired or wireless connection, and the disclosure suitably includes its equivalents.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A method performed by a device in a wireless communication system, the method comprising:
receiving, from a reader, first information for a device to reader (D2R) transmission; and
transmitting, to the reader, the D2R transmission based on the first information,
wherein the first information includes at least one of information on a frequency domain resource, information on a time domain resource, or a chip duration.

2. The method of claim 1, further comprising:
performing coding for the D2R transmission based on a line coding scheme, and
wherein the line coding scheme includes a Manchester encoding.

3. The method of claim 1, further comprising:
performing a modulation for the D2R transmission based on a modulation scheme, and
wherein the modulation scheme includes an on-off keying (OOK) modulation scheme.

4. The method of claim 1, wherein the first information further includes information on a modulation and coding scheme (MCS).

5. The method of claim 1, further comprising:
receiving, from the reader, a paging message including at least one identifier of the device or an identifier of a group for multiple devices,
wherein the device includes an ambient-internet of things (A-IoT) device.

6. A method performed by a reader in a wireless communication system, the method comprising:
transmitting, to a device, first information for a device to reader (D2R) transmission; and
receiving, from the device, the D2R transmission based on the first information,
wherein the first information includes at least one of information on a frequency domain resource, information on a time domain resource, or a chip duration.

7. The method of claim 6, wherein a line coding scheme for the D2R transmission includes a Manchester encoding.

8. The method of claim 6, wherein a modulation scheme for the D2R transmission includes an on-off keying (OOK) modulation scheme.

9. The method of claim 6, wherein the first information further includes information on a modulation and coding scheme (MCS).

10. The method of claim 6, further comprising:
transmitting, to the device, a paging message including at least one identifier of the device or an identifier of a group for multiple devices,
wherein the device includes an ambient-internet of things (A-IoT) device.

11. A device in a wireless communication system, the device comprising:
a transceiver; and
a controller coupled with the transceiver and configured to:
receive, from a reader, first information for a device to reader (D2R) transmission; and
transmit, to the reader, the D2R transmission based on the first information,
wherein the first information includes at least one of information on a frequency domain resource, information on a time domain resource, or a chip duration.

12. The device of claim 11, wherein the controller further configured to perform coding for the D2R transmission based on a line coding scheme, and
wherein the line coding scheme includes a Manchester encoding.

13. The device of claim 11, wherein the controller further configured to perform a modulation for the D2R transmission based on a modulation scheme, and
wherein the modulation scheme includes an on-off keying (OOK) modulation scheme.

14. The device of claim 11, wherein the first information further includes information on a modulation and coding scheme (MCS).

15. The device of claim 11, wherein the controller further configured to receive, from the reader, a paging message including at least one identifier of the device or an identifier of a group for multiple devices, and
wherein the device includes an ambient-internet of things (A-IoT) device.

16. A reader in a wireless communication system, the reader comprising:
a transceiver; and
a controller coupled with the transceiver and configured to:
transmit, to a device, first information for a device to reader (D2R) transmission; and
receive, from the device, the D2R transmission based on the first information,
wherein the first information includes at least one of information on a frequency domain resource, information on a time domain resource, or a chip duration.

17. The reader of claim 16, wherein a line coding scheme for the D2R transmission includes a Manchester encoding.

18. The reader of claim 16, wherein a modulation scheme for the D2R transmission includes an on-off keying (OOK) modulation scheme.

19. The reader of claim 16, wherein the first information further includes information on a modulation and coding scheme (MCS).

20. The reader of claim 16, wherein the controller further configured to transmit, to the device, a paging message including at least one identifier of the device or an identifier of a group for multiple devices, and
wherein the device includes an ambient-internet of things (A-IoT) device.
